(19) United States
(12) Patent Application Publication
(10) Pub. No.: US 2026/0054394 A1
(43) Pub. Date: Feb. 26, 2026

(54) SUBSTRATE TRANSFER APPARATUS, AND SUBSTRATE PROCESSING SYSTEM AND SUBSTRATE PROCESSING APPARATUS INCLUDING THE SAME

(71) Applicant: SCREEN Holdings Co., Ltd., Kyoto (JP)

(72) Inventor: Akihiro IWASAKI, Kyoto (JP)

(21) Appl. No.: 19/304,172

(22) Filed: Aug. 19, 2025

(30) Foreign Application Priority Data
Aug. 20, 2024 (JP) 2024-138961

(51) Int. Cl. B25J 15/00; B08B 3/10; B25J 11/00

(52) U.S. Cl. CPC B25J 15/0014; B25J 11/0095; B08B 3/10

(57) ABSTRACT

A dry substrate hand of the present invention includes a first branch blade, a pair of proximal end guides provided at a proximal end portion of the first branch blade and in contact with a substrate end portion, and a pair of distal end guides provided at a distal end portion of the first branch blade and in contact with the substrate end portion. The wet substrate hand of the present invention includes a second branch blade, a pair of proximal end protrusions provided at a proximal end portion of the second branch blade and in contact with a lower surface of a substrate to support the substrate, and a pair of distal end protrusions provided at a distal end portion of the second branch blade and in contact with the lower surface of the substrate to support the substrate.

This application claims priority to Japanese Patent Application No. 2024-138961 filed Aug. 20, 2024, the subject matter of which is incorporated herein by reference in entirety.

### BACKGROUND OF THE INVENTION

The present invention relates to a substrate processing system and a substrate processing apparatus capable of performing predetermined liquid processing on a substrate, and particularly relates to a substrate transfer apparatus for substrate transfer provided in the substrate processing system or the substrate processing apparatus.

### DESCRIPTION OF THE RELATED ART

JP 2020-188228 A describes a substrate transfer apparatus that can surely prevent scattering of a liquid when transferring a liquid-filled substrate. That is, the substrate transfer apparatus is a substrate transfer apparatus including a hand that holds a substrate, and includes a cover portion that accommodates the hand in a predetermined internal space. The liquid filled on the substrate, which is held by the hand, does not scatter to the outside of the cover portion.

### LIST OF DOCUMENTS

JP2020-188228

However, in the above configuration, consideration on transferring a dry substrate is insufficient. The substrate transfer apparatus of JP 2020-188228 A has a configuration specialized for transferring a liquid-filled substrate. In a case where it is necessary to transfer a dry substrate in addition to the liquid-filled substrate, the substrate transfer apparatus including only the hand for a wet substrate transfer causes a disadvantage that the dry substrate is wetted with a liquid adhered to the hand.

The present invention has been made in view of such circumstances, and an object of the present invention is to provide a substrate transfer apparatus that can surely transfer a dry substrate and a wet substrate, and a substrate processing system and a substrate processing apparatus including the same.

### SUMMARY OF THE INVENTION

In order to solve the above problem, the present invention has the following configuration. That is, a substrate transfer apparatus of the present invention is a substrate transfer apparatus that transfers a substrate, including:
at least one dry substrate hand for gripping a dry substrate in a horizontal posture;
a wet substrate hand provided below the dry substrate hand and for supporting a liquid-filled substrate;
a first moving mechanism that movably supports the dry substrate hand;
a second moving mechanism that movably supports the wet substrate hand; and
a base member that supports the first moving mechanism and the second moving mechanism, in which
the dry substrate hand includes:
   a first blade;
   a pair of proximal end guides provided at a proximal end portion of the first blade and in contact with a substrate end portion;
   a pair of distal end guides provided at a distal end portion of the first blade and in contact with the substrate end portion; and
   a pusher for substrate gripping that is disposed at a position at the proximal end portion of the first blade and sandwiched between a pair of first proximal end guides, and is capable of gripping a substrate in cooperation with the distal end guides by coming into contact with an end side of the substrate and pressing the substrate toward the distal end guides, and
the wet substrate hand includes:
a second blade;
   a pair of proximal end protrusions that is provided at a proximal end portion of the second blade and in contact with a lower surface of the substrate to support the substrate;
   a pair of distal end protrusions that is provided at a distal end portion of the second blade and in contact with the lower surface of the substrate to support the substrate.

[Operation and Effect] According to the above configuration, since the dry substrate hand and the wet substrate hand are provided individually, the dry substrate is not inadvertently wetted with the liquid. In addition, since the dry substrate hand and the wet substrate hand each have an individual substrate support structure corresponding to each application as described below, the dry substrate and the wet substrate can each be surely transferred. That is, the dry substrate hand includes the first branch blade, the pair of proximal end guides provided at the proximal end portion of the first branch blade and in contact with the substrate end portion, the pair of distal end guides provided at the distal end portion of the first branch blade and in contact with the substrate end portion, and the hand pusher for substrate gripping that is disposed at a position at the proximal end portion of the first branch blade and sandwiched between a pair of first proximal end guides and is capable of gripping the substrate in cooperation with the distal end guides by coming into contact with the end side of the substrate and pressing the substrate toward the distal end guides. With this configuration, it is possible to provide a substrate transfer apparatus capable of performing transfer at high speed in a state where the dry substrate is surely gripped.

In addition, the wet substrate hand includes a second blade, a pair of proximal end protrusions provided at a proximal end portion of the second blade and in contact with a lower surface of a substrate to support the substrate, and a pair of distal end protrusions provided at a distal end portion of the second blade and in contact with the lower surface of the substrate to support the substrate. Since the proximal end protrusions and the distal end protrusions are not in contact with the end portion of the substrate, a liquid filled on the substrate does not drip down along the proximal end protrusions and the distal end protrusions. If a member such as the pusher for substrate gripping provided in the dry substrate hand is pressed against the end portion of the substrate, there is a disadvantage that the liquid filled on the substrate drips down along the member.

According to the above configuration, the dry substrate hand is provided separately from the wet substrate hand. As described above, the configuration including the individual hands according to the wet state of the substrate prevents the dry substrate from being transferred by the wet hand. According to the configuration of the present invention, it is possible to transfer the substrate while the dry state of the substrate is surely maintained.

According to the above configuration, the wet substrate hand is provided below the dry substrate hand. With this configuration, the liquid dripping from the wet substrate hand is not transmitted to the dry substrate hand. This is because the dry substrate hand is provided above the wet substrate hand.

In addition, the substrate transfer apparatus described above preferably further includes:
a fixing vat that is supported by the base member below the wet substrate hand and collects a liquid that has dropped from the wet substrate hand;
a moving vat that is provided between the wet substrate hand and the fixing vat, and receives the liquid that has dropped from the wet substrate hand and guides the liquid to the fixing vat; and
a moving vat advance/retreat mechanism that advances and retreats the moving vat in a horizontal direction with respect to the base member.

[Operation and Effect] According to the above configuration, there are provided the fixing vat that is supported by the base member below the wet substrate hand and collects the liquid that has dropped from the wet substrate hand, and the moving vat that is provided between the wet substrate hand and the fixing vat and receives the liquid that has dropped from the wet substrate hand and guides the liquid to the fixing vat. With this configuration, the liquid dripping from the wet substrate hand is collected in the fixing vat. When the moving vat follows the advance/retreat movement of the wet substrate hand, the liquid filled on the substrate can be received by the moving vat regardless of the position of the wet substrate hand. Therefore, according to the above configuration, it is possible to provide a substrate transfer apparatus capable of suppressing scattering of liquid.

In addition, the substrate transfer apparatus described above preferably further includes:
a tray hand provided below the wet substrate hand; and
a third moving mechanism that movably supports the tray hand and is supported by the base member, in which
the tray hand preferably includes a tray that receives a liquid dropping from the wet substrate hand.

[Operation and Effect] According to the above configuration, there are provided the tray hand provided below the wet substrate hand and the third moving mechanism that movably supports the tray hand and is supported by the base member, and the tray hand includes the tray that receives the liquid dropping from the wet substrate hand. With this configuration, it is possible to form a tray that faithfully follows the wet substrate hand, so that the liquid filled on the substrate can be received by the tray. Therefore, according to the above configuration, it is possible to provide a substrate transfer apparatus capable of suppressing scattering of liquid.

In addition, in the substrate transfer apparatus described above,
the dry substrate hand preferably includes an upper hand and a lower hand that are two hands disposed vertically, and
the upper hand and the lower hand are each preferably movably supported by the first moving mechanism provided individually.

[Operation and Effect] According to the above configuration, the dry substrate hand includes the upper hand and the lower hand that are two hands disposed vertically, and the upper hand and the lower hand are movably supported by the first moving mechanism provided individually. With this configuration, the dry substrate before the substrate processing and the dry substrate after the substrate processing can be transferred by different hands. Therefore, it is possible to prevent the clean dry substrate after the substrate processing from being gripped by the hand contaminated by the dry substrate before the substrate processing. According to the above configuration, it is possible to provide a substrate transfer apparatus that improves reliability of substrate processing in a substrate processing apparatus.

The present specification describes an invention of a substrate processing system including the substrate transfer apparatus described above.

The substrate processing system includes:
a batch processing apparatus that performs batch processing of collectively processing a plurality of substrates;
a relay apparatus that receives the plurality of substrates subjected to batch processing from the batch processing apparatus, converts each of the substrates into a horizontal posture, fills a liquid on the substrate in the horizontal posture, and transfers the substrate;
a single substrate processing apparatus that receives the liquid-filled substrate transferred to the relay apparatus and performs single substrate processing of processing the substrates one by one; and
a control unit that controls the batch processing apparatus, the single substrate processing apparatus, and the relay apparatus, in which
the single substrate processing apparatus includes:
   a drying chamber capable of drying the substrates one by one;
   the substrate transfer apparatus; and
   an indexer robot that returns the dried substrate to a carrier, and
the control unit
   controls the substrate transfer apparatus to receive the liquid-filled substrate by the wet substrate hand and transfer the substrate to the drying chamber,
   controls the drying chamber to perform drying processing of a substrate,
   controls the substrate transfer apparatus to receive the substrate dried in the drying chamber by the dry substrate hand and transfer the substrate to the indexer robot, and
controls the indexer robot to return the dried substrate to the carrier.

[Operation and Effect] According to the above configuration, the control unit controls the substrate transfer apparatus to receive the liquid-filled substrate by the wet substrate hand and transfer the substrate to the drying chamber, controls the drying chamber to perform the drying processing of the substrate, and controls the substrate transfer apparatus to receive the substrate dried in the drying chamber by the dry substrate hand and transfer the substrate to the indexer robot. As described above, the configuration including the individual hands according to the wet state of the substrate prevents the dry substrate from being transferred by the wet hand. According to the configuration of the present invention, it is possible to transfer the substrate while the dry state of the substrate is surely maintained.

Similarly, the present specification describes an invention of a substrate processing apparatus including the substrate transfer apparatus described above.

The substrate processing apparatus includes the substrate transfer apparatus and performs single substrate processing of processing substrates one by one, and the substrate processing apparatus includes:
an indexer robot that transfers a substrate in an apparatus;
a processing block that performs substrate processing; and
a control unit that controls the apparatus, in which
the processing block includes:
   a liquid supply chamber that fills a liquid on a substrate;
   a drying chamber that receives the liquid-filled substrate and perform drying processing; and
   the substrate transfer apparatus, and
the control unit
   controls the indexer robot to extract the substrate from a carrier,
   controls the substrate transfer apparatus to receive the substrate extracted from the indexer robot by the dry substrate hand and transfer the substrate to the liquid supply chamber,
   controls the liquid supply chamber to fill a liquid on the substrate,
   controls the substrate transfer apparatus to receive, by the wet substrate hand, the liquid-filled substrate filled by the liquid supply chamber and transfer the substrate to the drying chamber,
   controls the drying chamber to perform drying processing of the substrate,
   controls the substrate transfer apparatus to receive the substrate dried in the drying chamber by the dry substrate hand and transfer the substrate to the indexer robot, and
   controls the indexer robot to return the dried substrate to the carrier.

[Operation and Effect] According to the above configuration, the control unit controls the substrate transfer apparatus to receive the substrate extracted from the indexer robot by the dry substrate hand and transfer the substrate to the liquid supply chamber, controls the liquid supply chamber to fill a liquid on the substrate, controls the substrate transfer apparatus to receive, by the wet substrate hand, the liquid-filled substrate filled by the liquid supply chamber and transfer the substrate to the drying chamber, controls the drying chamber to perform the drying processing of the substrate, and controls the substrate transfer apparatus to receive the substrate dried in the drying chamber by the dry substrate hand and transfer the substrate to the indexer robot. As described above, the configuration including the individual hands according to the wet state of the substrate prevents the dry substrate from being transferred by the wet hand. According to the configuration of the present invention, it is possible to transfer the substrate while the dry state of the substrate is surely maintained.

According to the present invention, it is possible to provide a substrate transfer apparatus that can surely transfer a dry substrate and a wet substrate, and a substrate processing system and a substrate processing apparatus including the same.

### BRIEF OF DESCRIPTION OF THE DRAWINGS

FIG. 1 is a plan view for describing an overall configuration of a substrate processing system according to Embodiment 1;

FIG. 2 is a plan view for describing an overall configuration of a batch processing apparatus according to Embodiment 1;

FIG. 3 is a cross-sectional view for describing a configuration of a carrier according to Embodiment 1;

FIG. 4 is a perspective view for describing a transfer block according to Embodiment 1;

FIG. 5 is a cross-sectional view for describing an operation of a reverse chuck according to Embodiment 1;

FIG. 6 is a cross-sectional view for describing the operation of the reverse chuck according to Embodiment 1;

FIG. 7 is a cross-sectional view for describing the operation of the reverse chuck according to Embodiment 1;

FIG. 8 is a cross-sectional view for describing the operation of the reverse chuck according to Embodiment 1;

FIG. 9 is a cross-sectional view for describing the operation of the reverse chuck according to Embodiment 1;

FIG. 10 is a cross-sectional view for describing the operation of the reverse chuck according to Embodiment 1;

FIG. 11 is a cross-sectional view for describing an operation of a relay transfer mechanism according to Embodiment 1;

FIG. 12 is a cross-sectional view for describing the operation of the relay transfer mechanism according to Embodiment 1;

FIG. 13 is a cross-sectional view for describing the operation of the relay transfer mechanism according to Embodiment 1;

FIG. 14 is a cross-sectional view for describing the operation of the relay transfer mechanism according to Embodiment 1;

FIG. 15 is a cross-sectional view for describing an opening/closing operation of the reverse chucks according to Embodiment 1;

FIG. 16 is a cross-sectional view for describing the opening/closing operation of the reverse chucks according to Embodiment 1;

FIG. 17 is a cross-sectional view for describing the opening/closing operation of the reverse chucks according to Embodiment 1;

FIG. 18 is a cross-sectional view for describing the opening/closing operation of the reverse chucks according to Embodiment 1;

FIG. 19 is a cross-sectional view for describing a liquid supply system to a substrate according to Embodiment 1;

FIG. 20 is a cross-sectional view for describing a state in which the substrate is placed on a carry-out path according to Embodiment 1;

FIG. 21 is a cross-sectional view for describing a state in which the substrate is placed on the carry-out path according to Embodiment 1;

FIG. 22 is a cross-sectional view for describing a state in which the substrate is placed on the carry-out path according to Embodiment 1;

FIG. 23 is a cross-sectional view for describing a state in which the substrate is placed on the carry-out path according to Embodiment 1;

FIG. 24 is a cross-sectional view for describing a state in which the substrate is placed on the carry-out path according to Embodiment 1;

FIG. 25 is a plan view for describing an overall configuration of a single substrate processing apparatus according to Embodiment 1;

FIG. 26 is a side view for describing the overall configuration of the single substrate processing apparatus according to Embodiment 1;

FIG. 27 is a plan view for describing a configuration of a center robot according to Embodiment 1;

FIG. 28 is a perspective view for describing the configuration of the center robot according to Embodiment 1;

FIG. 29A is a cross-sectional view for describing a configuration of a hand according to Embodiment 1;

FIG. 29B is a cross-sectional view for describing the configuration of the hand according to Embodiment 1;

FIG. 30 is a plan view for describing the configuration of the hand according to Embodiment 1;

FIG. 31 is a plan view for describing the configuration of the hand according to Embodiment 1;

FIG. 32 is a perspective view for describing a configuration of a bat according to Embodiment 1;

FIG. 33 is a perspective view for describing an operation of the bat according to Embodiment 1;

FIG. 34 is a perspective view for describing the operation of the bat according to Embodiment 1;

FIG. 35 is a perspective view for describing the operation of the bat according to Embodiment 1;

FIG. 36 is a perspective view for describing the operation of the bat according to Embodiment 1;

FIG. 37 is a perspective view for describing the operation of the bat according to Embodiment 1;

FIG. 38 is a flowchart for describing a flow of substrate processing according to Embodiment 1;

FIG. 39 is a plan view for describing a transfer path of the substrate in the substrate processing according to Embodiment 1;

FIG. 40 is a plan view for describing the transfer path of the substrate in the substrate processing according to Embodiment 1;

FIG. 41 is a plan view for describing the transfer path of the substrate in the substrate processing according to Embodiment 1;

FIG. 42 is a cross-sectional view for describing a method of transferring a wet substrate in the substrate processing according to Embodiment 1;

FIG. 43 is a plan view for describing the transfer path of the substrate in the substrate processing according to Embodiment 1;

FIG. 44 is a cross-sectional view for describing a method for transferring a dry substrate in the substrate processing according to Embodiment 1;

FIG. 45 is a plan view for describing a substrate processing apparatus according to Embodiment 2;

FIG. 46 is a flowchart for describing a flow of substrate processing according to Embodiment 2;

FIG. 47 is a plan view for describing a transfer path of a substrate in the substrate processing according to Embodiment 2;

FIG. 48 is a plan view for describing the transfer path of the substrate in the substrate processing according to Embodiment 2;

FIG. 49 is a plan view for describing the transfer path of the substrate in the substrate processing according to Embodiment 2;

FIG. 50 is a cross-sectional view for describing an apparatus configuration according to Modification 1 of the present invention;

FIG. 51 is a perspective view for describing the apparatus configuration according to Modification 1 of the present invention;

FIG. 52 is a perspective view for describing the apparatus configuration according to Modification 1 of the present invention; and

FIG. 53 is a cross-sectional view for describing the apparatus configuration according to Modification 1 of the present invention.

### DESCRIPTION OF THE PREFERRED EMBODIMENTS

Hereinafter, a substrate processing system and a substrate processing apparatus according to the present invention will be described with reference to the drawings. The substrate processing system of Embodiment 1 continuously performs batch processing of collectively processing a plurality of substrates W and single substrate processing of processing the substrates W one by one, and has a configuration in which a batch processing apparatus related to the batch processing and a single substrate processing apparatus related to the single substrate processing are coupled by a relay apparatus.

The substrate processing system according to Embodiment 1 performs, for example, each piece of processing such as chemical liquid processing, cleaning processing, and drying processing on the substrate W. The substrate processing system adopts a processing method (so-called hybrid method) in which both a batch-type processing method of collectively processing the plurality of substrates W and a single substrate type processing method of processing the substrates W one by one are used in combination. The batch-type processing method is a processing method of collectively processing the plurality of substrates W arranged in a vertical posture. The single substrate type processing method is a processing method of processing the substrates W in a horizontal posture one by one. The substrate processing system of the present invention continuously performs the batch processing of collectively processing the plurality of substrates and the single substrate processing of processing the substrates one by one. The substrate processing system of the present invention includes a batch processing apparatus and a single substrate processing apparatus. The batch processing apparatus performs the batch processing of collectively processing the substrates. The single substrate processing apparatus performs the single substrate processing of processing the substrates one by one.

That is, the substrate processing system of the present invention includes: a batch processing apparatus 1 that collectively processes the plurality of substrates W; a relay apparatus 6 that receives the plurality of substrates W subjected to batch processing from the batch processing apparatus 1, converts each of the substrates W into a horizontal posture, and transfers the substrate W in the horizontal posture while filling a liquid on the substrate W in the horizontal posture; and a single substrate processing apparatus 2 that receives the liquid-filled substrate W transferred to the relay apparatus 6 and performs single substrate processing of processing each of the substrates W one by one.

A substrate processing apparatus of Embodiment 2 is a substrate processing apparatus that performs predetermined processing on a substrate in a horizontal posture. The substrate processing apparatus according to Embodiment 2 does not necessarily need to be able to perform batch-type processing.

### Embodiment 1

### 1. Overall Configuration

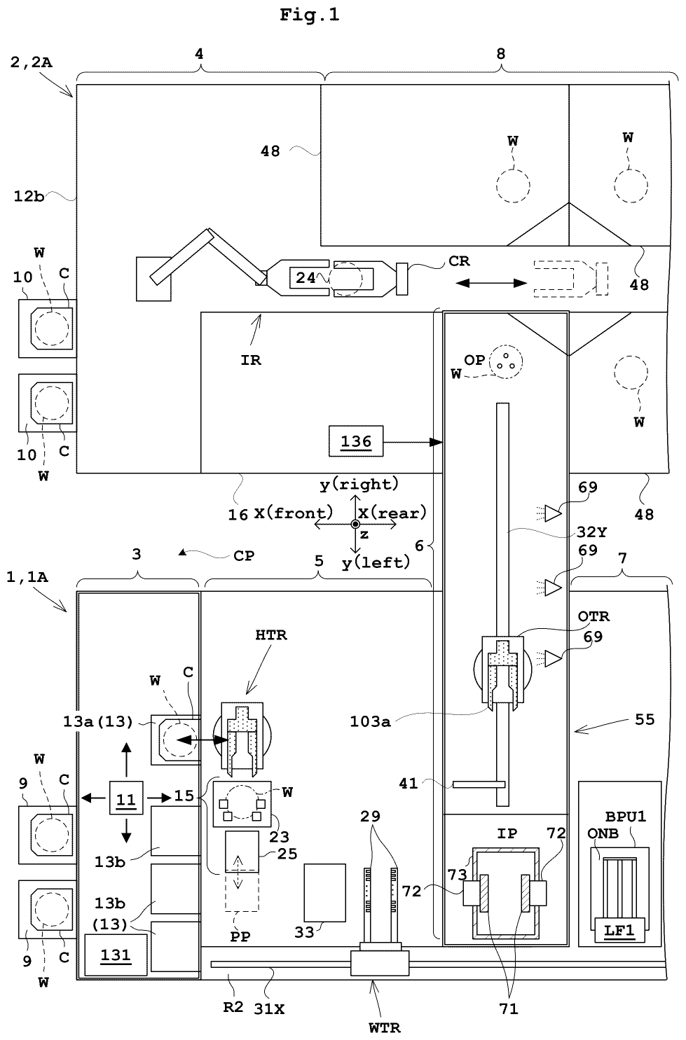

As illustrated in FIG. 1, the substrate processing system includes the batch processing apparatus 1 and the single substrate processing apparatus 2 that are individually constituted, and the relay apparatus 6 that couples the apparatuses 1 and 2. The batch processing apparatus 1 relates to batch processing of collectively processing a plurality of substrates, and the single substrate processing apparatus 2 relates to single substrate processing of processing the substrates one by one. The relay apparatus 6 transfers the substrates subjected to batch processing from the batch processing apparatus 1 to the single substrate processing apparatus 2, and has a bridge structure provided at a position interposed between the batch processing apparatus 1 and the single substrate processing apparatus 2.

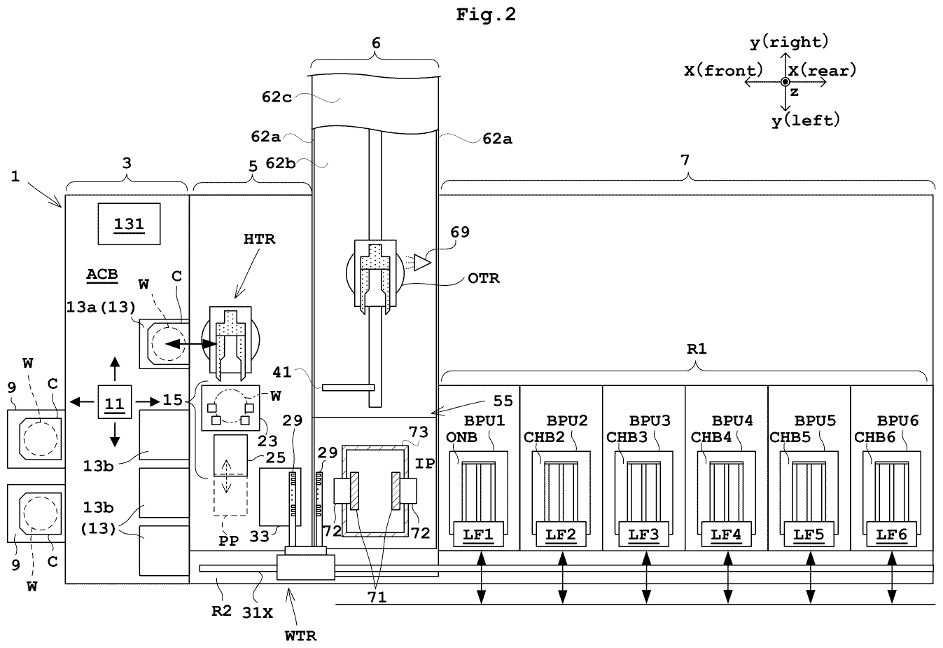

As illustrated in FIG. 1, each of the batch processing apparatus 1 and the single substrate processing apparatus 2 includes blocks partitioned by partition walls. That is, the batch processing apparatus 1 includes a stocker block 3, a transfer block 5 adjacent to the stocker block 3, and a batch processing block 7 adjacent to the transfer block 5. FIG. 2 illustrates a specific configuration of the batch processing block 7 in the batch processing apparatus 1. Meanwhile, the single substrate processing apparatus 2 includes an indexer block 4, and a single substrate processing block 8 adjacent to the indexer block 4.

The batch processing apparatus 1 performs the batch processing, and includes a first housing 1A that stores each of the blocks constituting the batch processing apparatus 1. The single substrate processing apparatus 2 performs the single substrate processing on the substrates W subjected to batch processing, and includes a second housing 2A that stores each of the blocks constituting the single substrate processing apparatus 2. Among wall surfaces constituting the first housing 1A, the first housing 1A includes a first load port 9 protruding from a first wall surface orthogonal to a Y direction which is a direction from the batch processing block 7 toward the transfer block 5. Among wall surfaces constituting the second housing 2A, the second housing 2A includes a second load port 10 protruding from a second wall surface orthogonal to the Y direction, and the second load port 10 is at the same position as the first load port 9 in the Y direction. A carrier C can be placed in the second load port 10.

In the present specification, for convenience, a direction in which the stocker block 3, the transfer block 5, and the batch processing block 7 in the batch processing apparatus 1 are arranged is referred to as a “front-rear direction X”. The front-rear direction X is also a direction in which the indexer block 4 and the single substrate processing block 8 in the single substrate processing apparatus 2 are arranged. The front-rear direction X extends horizontally. In the front-rear direction X, the direction from the transfer block 5 toward the stocker block 3 in the batch processing apparatus 1 is referred to as “front”. The front is also a direction from the single substrate processing block 8 toward the indexer block 4 in the single substrate processing apparatus 2. A direction opposite to the front is referred to as “rear”. A direction extending horizontally orthogonal to the front-rear direction X is referred to as a “width direction Y”. One direction of the “width direction Y” is referred to as “right” for convenience, and the other direction is referred to as “left” for convenience. A direction (height direction) orthogonal to the front-rear direction X and the width direction Y is referred to as a “vertical direction Z” for convenience. In each drawing, front, rear, right, left, top, and bottom are appropriately indicated for reference.

In the substrate processing system of the present invention, first, the first batch processing is performed on the substrates W in the batch processing apparatus 1, and the substrates W after the batch processing are transferred to the single substrate processing apparatus 2 by the relay apparatus 6. Thereafter, the substrates W are subjected to dry processing by the single substrate processing apparatus 2. Thereafter, the substrates W are subjected to the second batch processing in the batch processing apparatus 1 again. The substrates W subjected to the batch processing are transferred to the single substrate processing apparatus 2 by the relay apparatus 6 again. Then, the substrates W are subjected to the drying processing by the single substrate processing apparatus 2. Thereafter, the substrates W are stored in the carrier C placed in the second load port 10. In this way, the substrate processing system ends the entire process of the substrate processing. Hereinafter, specific configurations of the batch processing apparatus 1, the relay apparatus 6, and the single substrate processing apparatus 2 in the substrate processing system of the present invention will be described in this order.

### 2. Batch Processing Apparatus: Stocker Block

The stocker block 3 includes the first load port 9 which is an entrance where the carrier C that stores the plurality of substrates W in a horizontal posture at predetermined intervals in a vertical direction is input into the block. The first load port 9 protrudes from an outer wall of the stocker block 3 extending in the width direction (Y direction).

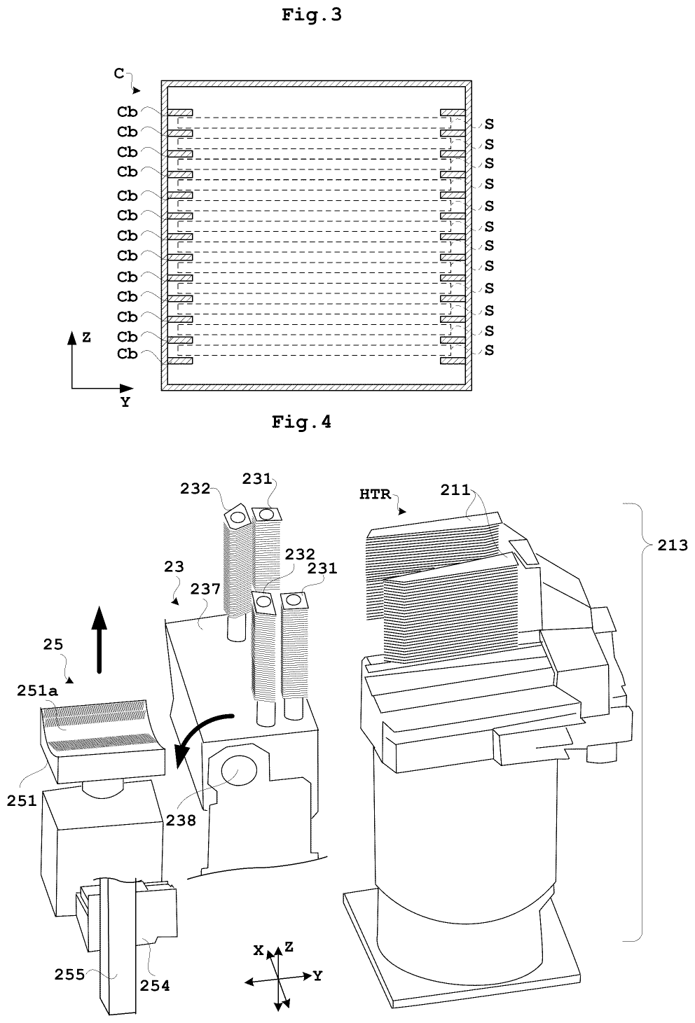

FIG. 3 describes a configuration of the carrier C of the present invention. In the carrier C, a plurality of slots S is formed extending in the horizontal direction to hold surfaces of the substrates W in a state of separating the surfaces from each other. The slots S are arranged in the vertical direction at a specific pitch (for example, 10 mm), and each of the substrates W is accommodated in a respective one of the slots S. There are 25 slots S provided in one carrier C. Therefore, in the carrier C, a substrate array is arranged in the vertical direction at the specific pitch. A placement plate Cb is located at a position where each slot S is divided, and supports both ends of the substrate W together with a placement plate Cb forming a pair. Therefore, the placement plates Cb are arranged one by one on a side surface of the carrier C and on a surface parallel to the side surface. Examples of the carrier C include a sealed-type front opening unify pod (FOUP). In the present invention, an opened-type container may be adopted as the carrier C.

An internal structure of the stocker block 3 will be described. The stocker block 3 includes a transfer/storage unit ACB that stocks and manages the carrier C. The transfer/storage unit ACB includes a carrier transfer mechanism 11 that transfers the carrier C, and a shelf 13 on which the carrier C is placed. The number of carriers C the stocker block 3 can stock is one or more.

The stocker block 3 includes a plurality of the shelves 13 on which the carrier C is placed. The shelves 13 are provided on the partition wall separating the stocker block 3 and the transfer block 5. The shelves 13 include a shelf 13b for stocking on which the carrier C is simply temporarily placed, and a carrier placement shelf 13a for substrate extraction that is accessed by a handling robot HTR included in the transfer block 5.

The carrier C that stores a plurality of substrates in a horizontal posture at predetermined intervals in the vertical direction, can be placed on carrier placement shelf 13a. On the carrier placement shelf 13a, the carrier C from which the substrate W is to be extracted is placed. In the present embodiment, one carrier placement shelf 13a is provided, but a plurality of the carrier placement shelves 13a may be provided. The carrier transfer mechanism 11 takes in the carrier C storing the unprocessed substrate W from the first load port 9 and places the carrier C on the carrier placement shelf 13a for substrate extraction. At this time, the carrier transfer mechanism 11 can also temporarily place the carrier C on the shelf 13b for stocking before placing the carrier C on the carrier placement shelf 13a. The number of carrier placement shelves 13a included in the stocker block 3 is one or more.

### 3. Batch Processing Apparatus: Transfer Block

The transfer block 5 is adjacent to the carrier placement shelf 13a. The transfer block 5 is disposed adjacent to and behind the stocker block 3. The transfer block 5 includes the handling robot HTR that can access the carrier C placed on the carrier placement shelf 13a for substrate extraction, an HVC posture converting unit 23 that collectively converts the posture of the plurality of substrates W from the horizontal posture into the vertical posture, and a pusher mechanism 25. The HVC posture converting unit 23 collectively converts the plurality of substrates W from the horizontal posture into the vertical posture. Furthermore, in the transfer block 5, a substrate delivery position PP for delivering the plurality of substrates W to a substrate transfer mechanism WTR provided in a collective transfer region R2 is set.

As illustrated in FIG. 4, the handling robot HTR, the HVC posture converting unit 23, and the pusher mechanism 25 are arranged in this order in the Y direction. The handling robot HTR includes hands 211 that can grip the substrate W in the horizontal posture. The hands 211 can grip one substrate W. In the handling robot HTR, the hands 211 are arranged in the vertical direction. The handling robot HTR can transfer the plurality of substrates W at once by gripping the substrates with each of the hands 211. A movement support mechanism 213 is a mechanism constituting the handling robot HTR, and is configured to rotate the hands 211 around a vertical axis, lift and lower the hands 211, advance and retreat the hands 211 in the front-rear direction X, and traverse the hands 211 in the left-right direction Y.

The handling robot HTR includes 25 hands 211. The handling robot HTR collectively transfers the 25 substrates stored in the carrier C by these 25 hands 211.

The HVC posture converting unit 23 converts the substrates W, which are extracted from the carrier C by the handling robot HTR, from the horizontal posture into the vertical posture. The HVC posture converting unit 23 includes a pair of placing rods 231 and a pair of clamping rods 232 extending in a longitudinal direction (Z direction). A support base 237 includes a support surface extending in an XY plane supporting the placing rods 231 and the clamping rods 232. A rotation drive mechanism 238 makes the placing rods 231 and the clamping rods 232 rotate together with the support base 237 by 90°. This rotation causes the placing rods 231 and the clamping rods 232 to extend in the left-right direction (Y direction).

The pusher mechanism 25 includes a pusher 251 that can make the substrates W in the vertical posture to be arranged in the horizontal direction. The pusher 251 has a shape of a half pipe that is along the curve of a bottom portion of the substrate W. The pusher 251 in an initial state has a U-shaped groove 251a, which constitutes the half pipe, extending in the left-right direction Y. The pusher 251 in this state is capable of receiving the substrate W from the HVC posture converting unit 23.

A pusher shift mechanism 254 can reciprocate the pusher 251 in the initial state in the left-right direction Y. The pusher shift mechanism 254 can bring the pusher 251 close to the HVC posture converting unit 23 or can bring the pusher 251 close to the substrate transfer mechanism WTR.

The pusher lifting/lowering mechanism 255 can lift the pusher 251 at an initial position to an upper position. In addition, the pusher lifting/lowering mechanism 255 can also return the pusher 251 in the upper position to the initial position.

A state in which the substrates W in the horizontal posture acquired from the carrier C by the handling robot HTR are transferred to the pusher 251 will be described. First, the handling robot HTR collectively acquires, by making the hands 211 face forward, the substrate array in the horizontal posture from the carrier C. Thereafter, the handling robot HTR rotates the hands 211 about a rotation axis extending vertically, and turns the hands 211 toward the HVC posture converting unit 23 as illustrated in FIG. 4. Note that, in FIG. 4, the substrates W held by the hands 211 are omitted.

Thereafter, the hands 211 passes the substrate array to the HVC posture converting unit 23. The substrates W at this time are held by the pair of placing rods 231.

The HVC posture converting unit 23 that has acquired the substrate array operates the rotation drive mechanism 238 as indicated by an arrow in FIG. 4 to convert the posture of the substrates W constituting the substrate array from the horizontal posture to the vertical posture. As a result, the substrates W in the horizontal posture arranged in the vertical direction are set in the vertical posture and arranged in the left-right direction Y (horizontal direction). The substrates W at this time are separated from the pair of placing rods 231 and supported by the pair of clamping rods 232.

Before the rotation operation of the HVC posture converting unit 23, the pusher mechanism 25 moves the pusher 251 downward as illustrated in FIG. 4 and waits until the substrate array arrives. Thereafter, the pusher mechanism 25 lifts the pusher 251 toward the substrates W supported by the clamping rods 232 as indicated by an arrow in FIG. 4. Then, the substrates W are pushed up by the pusher 251 and separated from the clamping rods 232, and are finally held only by the pusher 251. In this manner, the pusher mechanism 25 acquires the substrates W from the HVC posture converting unit 23.

By repeating such acquisition of the substrate array twice, the pusher mechanism 25 can form a lot in which 50 substrates are arranged in the horizontal direction. The lot includes the substrates W for the two carriers C described with reference to FIG. 3, and an arrangement pitch of the substrates W in the lot is half (5 mm) of an arrangement pitch of the substrates W in the carrier C. In addition, in the substrate processing apparatus of the present invention, it is also possible to add an operation of rotating the pusher 251 by 180° about the vertical axis between the first substrate array acquisition operation and the second substrate array acquisition operation. Such a lot is a kind of substrate array in the present invention.

The substrate array support unit 33 can temporarily stock the substrate array including dry substrates. The substrate transfer mechanism WTR can cause the substrate array support unit 33 to make the substrate row before chemical liquid processing to wait in a case where the congestion of the substrate row occurs in the subsequent chemical liquid processing.

### 4. Batch Processing Apparatus: Batch Processing Block

The batch processing block 7 is adjacent to the transfer block 5. The batch processing block 7 performs the batch processing on the lot described above. The batch processing block 7 is divided into a batch processing region R1 and the collective transfer region R2 arranged in the width direction (Y direction). Each region extends in the front-rear direction (X direction). Specifically, the batch processing region R1 is disposed inside the batch processing block 7. The collective transfer region R2 is adjacent to the batch processing region R1 and is disposed on the leftmost side of the batch processing block 7 (see FIG. 2).

### 5. Batch Processing Block: Batch Processing Region

The batch processing region R1 in the batch processing block 7 is a rectangular region extending in the front-rear direction (X direction). One end side (front side) of the batch processing region R1 is adjacent to the relay apparatus 6. The other end side of the batch processing region R1 extends in a direction (rear side) away from the transfer block 5 and the relay apparatus 6. Therefore, the relay apparatus 6 is an apparatus that is inserted at a position where the batch processing apparatus 1 is divided from the middle. In a case where the substrate array is transferred from the batch processing apparatus 1 to the relay apparatus 6, a second substrate transfer mechanism WTR included in the batch processing apparatus 1 is used.

The second substrate transfer mechanism WTR collectively transfers the plurality of substrates W in the vertical posture among the transfer block 5, batch processing units BPU1 to BPU6, and a carry-in position IP in the relay apparatus 6. Therefore, the collective transfer region R2, which is a region where the second substrate transfer mechanism WTR can move, is not divided by the relay apparatus 6 and extends in the Y direction along a left end portion of the relay apparatus 6. The relay apparatus 6 is fitted inside the batch processing apparatus 1, but does not reach the left end of the batch processing apparatus 1. This is because the collective transfer region R2 is provided at the left end of the batch processing apparatus 1.

The batch processing region R1 includes a batch-type processing unit that mainly performs batch-type processing. Specifically, in the batch processing region R1, there is arranged a plurality of batch processing units BPU1 to BPU6 that collectively perform immerse processing on the plurality of substrates W in a direction in which the batch processing region R1 extends. The batch processing units BPU1 to BPU6 collectively perform the immerse processing on the plurality of substrates in the vertical posture. The arrangement of the batch processing units BPU1 to BPU6 will be specifically described. The first batch processing unit BPU1 is adjacent to the relay apparatus 6 from the rear. The second batch processing unit BPU2 is adjacent to the first batch processing unit BPU1 from the rear. The third batch processing unit BPU3 is adjacent to the second batch processing unit BPU2 from the rear. The fourth batch processing unit BPU4 is adjacent to the third batch processing unit BPU3 from the rear. The fifth batch processing unit BPU5 is adjacent to the fourth batch processing unit BPU4 from the rear. The sixth batch processing unit BPU6 is adjacent to the fifth batch processing unit BPU5 from the rear. Therefore, the first batch processing unit BPU1, the second batch processing unit BPU2, the third batch processing unit BPU3, the fourth batch processing unit BPU4, the fifth batch processing unit BPU5, and the sixth batch processing unit BPU6 are disposed away from the relay apparatus 6 in this order. In FIG. 1, the second batch processing unit BPU2 to the sixth batch processing unit BPU6 are omitted for convenience of drawing. This configuration can be understood by referring to FIG. 2.

The batch processing units BPU1 to BPU6 each include a batch processing tank of the present invention. The batch processing tank is a liquid tank that holds a chemical liquid or pure water. The chemical liquid can be an acidic aqueous solution, for example, a phosphoric acid aqueous solution. In the present specification, the chemical liquid and pure water are collectively referred to as a processing liquid. The batch processing tanks for holding the chemical liquid are referred to as batch chemical liquid processing tanks CHB2 to CHB6, and the batch processing tank for holding pure water is referred to as a batch rinse processing tank ONB.

Specifically, the second batch processing unit BPU2 includes the batch chemical liquid processing tank CHB2 that collectively performs chemical liquid processing on the substrate array, and a lifter LF2 that lifts and lowers the substrate array between a substrate delivery position and a chemical liquid processing position (see FIG. 2). The substrate delivery position is a position set above the batch chemical liquid processing tank CHB2 accessible by the second substrate transfer mechanism WTR, and the chemical liquid processing position is a position set inside the batch chemical liquid processing tank CHB2 capable of immersing the substrate array in the chemical liquid. The batch chemical liquid processing tank CHB2 performs acid processing on the substrate array. The acid processing can be a phosphoric acid processing, but may be a processing using another acid. In the phosphoric acid processing, etching processing is performed on the plurality of substrates W constituting the substrate array. In the etching processing, for example, the nitride film on the surface of the substrate W is chemically etched.

The batch chemical liquid processing tank CHB2 accommodates an acid solution such as a phosphoric acid solution. The batch chemical liquid processing tank CHB2 is provided with the lifter LF2 that moves the substrate array up and down. The lifter LF2 ascends and descends in the vertical direction (Z direction). Specifically, the lifter LF2 ascends and descends across the processing position corresponding to the inside of the batch chemical liquid processing tank CHB2 and the delivery position corresponding to the above of the batch chemical liquid processing tank CHB2. The lifter LF2 holds the substrate array including the substrates W in the vertical posture. The lifter LF2 delivers the substrate array to and from the second substrate transfer mechanism WTR at the delivery position. When the lifter LF2 descends from the delivery position to the processing position while holding the substrate array, the entire region of the substrate W is located under the liquid level of the chemical liquid. When the lifter LF2 ascends from the processing position to the delivery position while holding the substrate array, the entire region of the substrate W is located above the liquid level of the chemical liquid. The lifter LF2 can collectively immerse, in the batch processing tank, the plurality of substrates in the vertical posture subjected to posture conversion by the HVC posture converting unit 23. At this time, the lifter LF2 descends from the delivery position to the processing position.

Specifically, the third batch processing unit BPU3 includes the batch chemical liquid processing tank CHB3, and a lifter LF3 that lifts and lowers the substrate array between the substrate delivery position and the chemical liquid processing position. The batch chemical liquid processing tank CHB3 has the configuration similar to the batch chemical liquid processing tank CHB2 described above. That is, the batch chemical liquid processing tank CHB3 accommodates the chemical liquid described above, and is provided with the lifter LF3. The batch chemical liquid processing tank CHB3 performs the processing, on the substrate array, similar to the batch chemical liquid processing tank CHB2. The batch processing apparatus 1 of the present embodiment includes a plurality of processing tanks capable of performing the same chemical liquid processing. This is because the phosphoric acid processing takes more time than other processing. The phosphoric acid processing requires a long time (for example, 60 minutes). Therefore, in the apparatus of the present embodiment, the acid processing can be performed in parallel by the plurality of batch chemical liquid processing tanks.

The fourth batch processing unit BPU4 to the sixth batch processing unit BPU6 each have the configuration similar to the second batch processing unit BPU2 and the third batch processing unit BPU3. That is, the fourth batch processing unit BPU4 includes the batch chemical liquid processing tank CHB4, and a lifter LF4 that lifts and lowers the substrate array between the substrate delivery position and the chemical liquid processing position. Similarly, the fifth batch processing unit BPU5 includes the batch chemical liquid processing tank CHB5, and a lifter LF5 that lifts and lowers the substrate array between the substrate delivery position and the chemical liquid processing position. The sixth batch processing unit BPU6 includes the batch chemical liquid processing tank CHB6, and a lifter LF6 that lifts and lowers the substrate array between the substrate delivery position and the chemical liquid processing position. Therefore, the substrate array is acid-processed in any one of the batch chemical liquid processing tank CHB2 to the batch chemical liquid processing tank CHB6. By performing the chemical liquid processing in parallel by the five processing units in this manner, the throughput of the apparatus is increased.

Specifically, the first batch processing unit BPU1 includes the batch rinse processing tank ONB that accommodates a rinse liquid, and a lifter LF1 that lifts and lowers the substrate array between the substrate delivery position and a rinse position. The substrate delivery position is a position set above the batch rinse processing tank ONB accessible by the second substrate transfer mechanism WTR, and the rinse position is a position set inside the batch rinse processing tank ONB capable of immersing the substrate array in the rinse liquid. The batch rinse processing tank ONB has the configuration similar to the batch chemical liquid processing tank CHB2 described above. That is, the batch rinse processing tank ONB accommodates the rinse liquid and is provided with the lifter LF1. Unlike other processing tanks, the batch rinse processing tank ONB accommodates pure water, and is provided for the purpose of cleaning the chemical liquid adhered to the plurality of substrates W. In the batch rinse processing tank ONB, when the specific resistance of pure water in the tank increases to a predetermined value, the cleaning processing ends.

As described above, the batch rinse processing tank ONB in the present embodiment is located closer to the relay apparatus 6 than the batch chemical liquid processing tanks CHB2 to CHB6. With such a configuration, each mechanism constituting the relay apparatus 6 and the batch chemical liquid processing tank CHB2 to the batch chemical liquid processing tank CHB6 are separated as much as possible, and the relay apparatus 6 is not adversely affected by an acid such as phosphoric acid. In addition, by disposing the relay apparatus 6 and the batch rinse processing tank ONB close to each other, the substrate array for which the rinse processing has been completed is transferred by a short distance and immediately carried into the relay apparatus 6. Therefore, according to the configuration of the present embodiment, the transfer of the substrates W can be quickly completed while the wet state of the substrates W is maintained.

### 6. Batch Processing Block: Collective Transfer Region

The collective transfer region R2 in the batch processing block 7 is a rectangular region extending in the front-rear direction (X direction). The collective transfer region R2 is provided along an outer edge of the batch processing region R1, and has one end side extending to the transfer block 5 and the other end side extending in a direction away from the transfer block 5. Therefore, the collective transfer region R2 is provided also along the relay apparatus 6 which is at a position sandwiched between the transfer block 5 and the batch processing block 7.

In the collective transfer region R2, the second substrate transfer mechanism WTR that collectively transfers the plurality of substrates W is provided. The second substrate transfer mechanism WTR collectively transfers the substrate array among the substrate delivery position PP defined in the transfer block 5, the substrate array support unit 33, each of the batch processing units BPU1 to BPU6, and the carry-in position IP in the relay apparatus 6 described later. The second substrate transfer mechanism WTR can reciprocate in the front-rear direction (X direction) across the transfer block 5, the relay apparatus 6, and the batch processing block 7. The second substrate transfer mechanism WTR is movable not only to the collective transfer region R2 in the batch processing block 7 but also to the substrate delivery position PP in the transfer block 5, the substrate array support unit 33, and the carry-in position IP in the relay apparatus 6.

The second substrate transfer mechanism WTR includes a pair of chucks 29 that transfer the substrate array. The pair of chucks 29 can be changed to a closed state in which the chucks 29 are close to each other and an open state in which the chucks 29 are separated from each other. The chucks 29 are each a member extending in the Y direction in which grooves for gripping the substrate W are arranged at a full pitch (the pitch same as the substrate array). The pair of chucks 29 gets in the closed state to receive the plurality of substrates W constituting the substrate array. Then, the pair of chucks 29 gets in the opened state to pass the plurality of substrates W constituting the substrate array to another member (such as the lifter LF1). The second substrate transfer mechanism WTR transfers the substrate array among the substrate delivery position PP in the transfer block 5, the substrate array support unit 33, and an immersion tank 73 provided at the carry-in position IP in the relay apparatus 6. In addition, the second substrate transfer mechanism WTR transfers the substrate array among the lifters LF1 to LF6 belonging to the batch processing units BPU1 to BPU6, respectively, in the batch processing block 7.

The collective transfer region R2 is provided with a guide rail 31X extending in the X direction, that guides the second substrate transfer mechanism WTR. The second substrate transfer mechanism WTR can move forward and backward in the X direction along the guide rail 31X. Therefore, the guide rail 31X extends from the batch processing block 7 to the transfer block 5 via the relay apparatus 6. More specifically, the guide rail 31X faces the substrate delivery position PP in the transfer block 5 from the Y direction, and faces the sixth batch processing unit BPU6 in the batch processing block 7 from the Y direction. In addition, the guide rail 31X faces the substrate array support unit 33 in the transfer block 5, the immersion tank 73 in the relay apparatus 6, and the first batch processing unit BPU1 to the sixth batch processing unit BPU6 in the batch processing block 7, from the Y direction.

### 7. Relay Apparatus

The relay apparatus 6 is configured to bridge the batch processing apparatus 1 and the single substrate processing apparatus 2, and has a left end fitted into the batch processing apparatus 1 and a right end fitted into the single substrate processing apparatus 2. The relay apparatus 6 includes a transfer path of the substrates W extending in the Y direction, that couples the collective transfer region R2 of the batch processing apparatus 1 to the single substrate processing region R3 of the single substrate processing apparatus 2. The transfer path transfers the substrates W in the Y direction (horizontal) without changing the position of the substrate W in the Z direction. Therefore, an insertion position of the relay apparatus 6 in the batch processing apparatus 1 and an insertion position of the relay apparatus 6 in the single substrate processing apparatus 2 are at the same position in the Z direction.

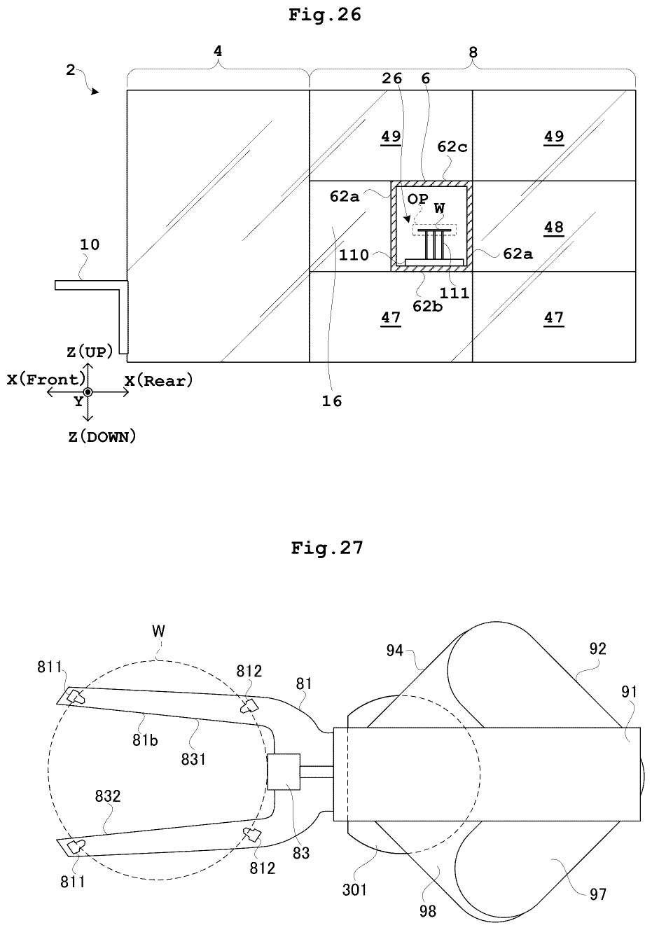

The relay apparatus 6 transfers the substrates W subjected to batch processing from the batch processing apparatus 1 to the single substrate processing apparatus 2. The relay apparatus 6 is located at a middle layer between the batch processing apparatus 1 and the single substrate processing apparatus 2 (see FIG. 26). Therefore, the relay apparatus 6 bridges the batch processing apparatus 1 and the single substrate processing apparatus 2 at a position in the air away from a floor surface on which the batch processing apparatus 1 and the single substrate processing apparatus 2 are installed. Since the specific position of the relay apparatus 6 is related to the structure of the single substrate processing apparatus 2, the specific position will be described in detail in accordance with the description of the single substrate processing apparatus 2.

The relay apparatus 6 includes reverse chucks 71 that receive the plurality of substrates W arranged in the Y direction and collectively rotates, in water, the received substrates W by 90° to convert the posture of the plurality of substrates W from the vertical posture to the horizontal posture, a relay transfer mechanism OTR that transfers the substrates W in the horizontal posture one by one to a carry-out position OP, and a path capable of holding the substrates W in the horizontal posture. The reverse chucks 71, the relay transfer mechanism OTR, and the path are arranged in this order in the right direction starting from a left portion of the batch processing apparatus 1. The carry-in position IP at which the substrate array is carried in from the batch processing apparatus 1 is set in the immersion tank 73. Therefore, in the relay apparatus 6, the carry-in position IP and the carry-out position OP where the path is provided are disposed in the left-right direction orthogonal to the front-rear direction. Hereinafter, each unit will be specifically described.

### 8. Relay Apparatus: Underwater Converting Unit

The reverse chucks 71 convert the substrate array received from the batch processing apparatus 1 from the vertical posture to the horizontal posture. The carry-in position IP includes the immersion tank 73 that holds pure water, the reverse chucks 71 located above the immersion tank 73, and a pair of chuck support mechanisms 72 that holds the respective reverse chucks 71 and lifts/lowers and rotates the reverse chucks 71. The reverse chucks 71 can ascend and descend from the substrate delivery position, which is set above the liquid level of the immersion tank 73 and to which the substrate transfer mechanism WTR delivers, to the inside of the liquid of the immersion tank 73. The reverse chuck 71 immerses the substrate array received from the substrate transfer mechanism WTR in the immersion tank 73, and can rotate by 90° in one direction or in the opposite direction in that state. The posture of the plurality of substrates W in the vertical posture is converted into the horizontal posture by the rotation of the pair of reverse chucks 71.

The reverse chucks 71 can change their states between a closed state in which the plurality of substrates W can be held and an opened state in which the plurality of held substrates W are opened, by the operation of the pair of chuck support mechanisms 72. In addition, the reverse chuck 71 can rotate by 90° in one direction or in the opposite direction in a state where the positional relationship between the reverse chucks 71 is maintained, by the operation of the pair of chuck support mechanisms 72. The reverse chucks 71 can ascend and descend from above the immersion tank 73 to the inside of the liquid in the immersion tank 73 in a state where the positional relationship between the reverse chucks 71 is maintained, by the operation of the pair of chuck support mechanisms 72.

The reverse chucks 71 each have a comb shape in which a plurality of V-shaped grooves is provided at intervals of a full pitch, and the pair of reverse chucks 71 holds the plurality of substrates W from both sides by fitting the plurality of substrates W into the V-shaped grooves. When the reverse chucks 71 get in the closed state, each of substrate ends abuts on the deepest portion of the V-shaped groove, and even if the reverse chucks 71 are rotated in this state, the substrates W do not slide off the reverse chucks 71. When the reverse chucks 71 get in the opened state, it is possible to receive the plurality of substrates W from the substrate transfer mechanism WTR holding the substrates W above the immersion tank 73 and waiting. In addition, the reverse chucks 71 can take a state between the closed state and the opened state (half-open state), which state will be described later.

### 9. Relay Apparatus: Relay Transfer Mechanism

The relay transfer mechanism OTR is a mechanism provided between the carry-in position IP and the carry-out position OP, and can transfer the substrates W in the horizontal posture subjected to posture conversion by the reverse chucks 71 to the single substrate processing apparatus 2 one by one. As illustrated in FIG. 1, the relay transfer mechanism OTR is guided by a relay rail 32Y extending in the Y direction from the immersion tank 73 (carry-in position IP) to the carry-out position OP to be described later, and can move in the Y direction. The relay transfer mechanism OTR includes a hand 103b capable of supporting the substrate W in the horizontal posture. The substrate W supported by the hand 103b is in a paddle state (liquid-filled state) by pure water. The relay transfer mechanism OTR makes the hand 103b to face the immersion tank 73, and can receive the substrates W in the horizontal posture one by one from the reverse chucks 71. In addition, the relay transfer mechanism OTR can transfer the substrate to the carry-out position OP.

Specifically, the hand 103b has the configuration similar to a wet substrate hand 82 described later. A specific configuration of the hand 82 for wet substrate will be described mainly with reference to FIG. 31.

### 10. Operation of Relay Apparatus

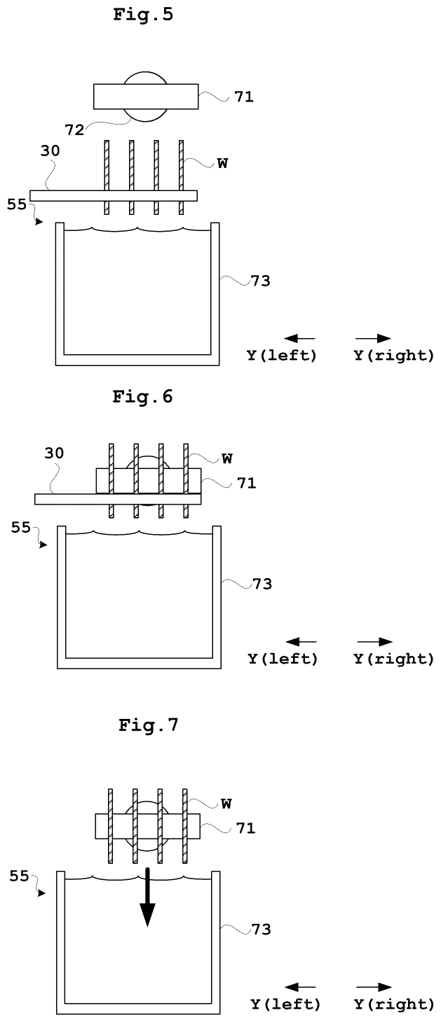

Next, a state in which the relay apparatus 6 transfers the substrate array acquired at the carry-in position IP to the carry-out position OP, will be described. FIG. 5 illustrates a state when the substrate transfer mechanism WTR transfers the plurality of substrates W to the above of the immersion tank 73. The pair of reverse chucks 71 at this time is located above the substrate transfer mechanism WTR, and a rotation angle is 0° which is the initial state. The reverse chucks 71 in the initial state extends in the horizontal direction, and can receive the plurality of substrates W in the vertical posture.

FIG. 6 illustrates a state in which the reverse chucks 71 then descend to the substrate transfer mechanism WTR. The operation of the reverse chucks 71 is realized by the chuck support mechanisms 72. FIG. 6 illustrates a state in which the substrate array is passed from the chucks 29 of the substrate transfer mechanism WTR to the reverse chucks 71. That is, the pair of reverse chucks 71 descends to the substrate transfer mechanism WTR while maintaining the opened state, and then gets in the closed state. Since the pair of reverse chucks 71 in the opened state is separated to pass the substrates W, it is possible to approach the chucks 29 without having a contact with the substrates W. Thereafter, the reverse chucks 71 get in the closed state by the operation of the chuck support mechanisms 72, and grip the substrate array. The substrate array at this time is gripped by both the chucks 29 and the reverse chucks 71. Thereafter, the chucks 29 get in the opened state and retreat in the Y direction (left direction). In this manner, the delivery of the substrates W from the chucks 29 to the reverse chucks 71 is executed. FIG. 7 illustrates a state in which the substrate array is passed to the reverse chucks 71. As indicated by an arrow in FIG. 7, the reverse chucks 71 descends under the liquid level of the immersion tank 73, and immerses the substrate array in pure water held by the immersion tank 73.

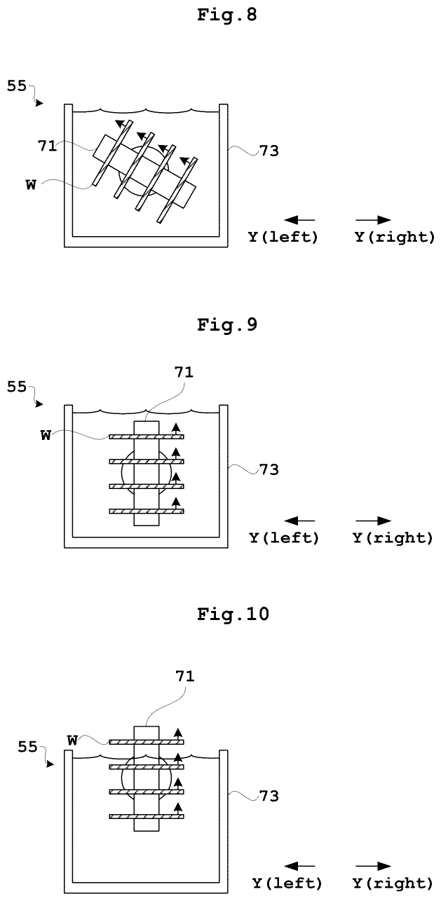

FIG. 8 illustrates a state in which the reverse chucks 71 are then rotating by 90° in a state in which the substrate array is immersed in pure water. The operation of the reverse chucks 71 is realized by the chuck support mechanisms 72. FIG. 9 illustrates a state in which the reverse chucks 71 complete the rotation of 90°. In this manner, a device surface of the substrate array immersed in the immersion tank 73 and facing the Y direction (left direction) is rotated by 90° and faces upward. When the substrates W are tilted in this manner, the posture of the substrates W can be set to the horizontal posture with the device surface facing upward. Thereafter, the substrates W in the horizontal posture are transferred with the device surface facing upward.

FIG. 10 illustrates a state when the reverse chucks 71 then moves one substrate in the substrate array to the above of the liquid level of the immersion tank 73. The operation of the reverse chucks 71 is realized by the chuck support mechanisms 72. According to FIG. 10, there is only one substrate W above the liquid level, and the remaining 24 substrates W are under the liquid level in the immersion tank 73. With such a configuration, 24 substrates W do not get dried during the wait for transfer. One substrate W above the liquid level is transferred to the carry-out position OP by the relay transfer mechanism OTR while maintaining the horizontal posture. Thereafter, the chuck support mechanisms 72 lifts the pair of reverse chucks 71 by a height corresponding to the full pitch every time the relay transfer mechanism OTR transfers the substrates W. When this operation is repeated, the entire substrate array is transferred to the carry-out position OP by the relay transfer mechanism OTR.

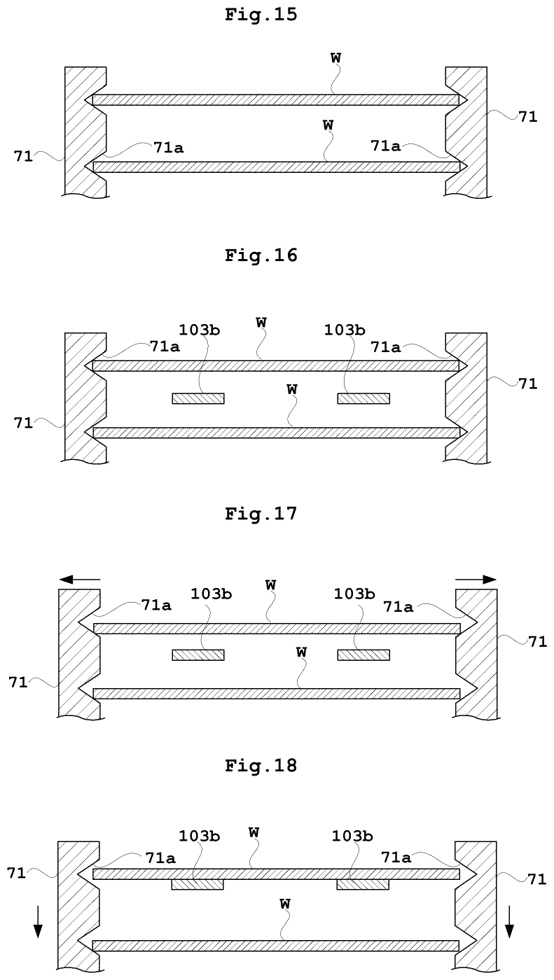

The opening/closing operation of the reverse chucks 71 in each state of FIGS. 5 to 10 will be described. As described above, the pair of reverse chucks 71 in the state of FIG. 5 is in the opened state and is not in a state of being able to grip the substrates W. Since the reverse chucks 71 in the opened state can pass through the substrates W, the reverse chucks 71 can move to the position illustrated in FIG. 6 without colliding with the substrates W. In FIG. 6, the pair of reverse chucks 71 is switched from the opened state to the closed state. At this time, each of the V-shaped grooves included in the pair of reverse chucks 71 causes each of end portions in the substrate array to enter and abut. How the substrates W fit into the respective V-shaped grooves will be described in detail in FIG. 15. The pair of reverse chucks 71 in FIGS. 7 to 9 is in the closed state and is in a state of gripping the substrates W. In this state, even if the reverse chucks 71 are rotated, the substrates W to be gripped are not dropped.

In order to realize the state of FIG. 10, it is necessary to devise to prevent the substrates W waiting in the immersion tank 73 from being dropped while allowing the transfer of the substrates W by the relay transfer mechanism OTR. Therefore, according to the present embodiment, the pair of reverse chucks 71 is brought into a half-opened state in the state of FIG. 10. As a result, a state is realized in which the substrates W are supported so that the substrates W can be taken out. The half-opened state will be described in detail in FIGS. 17 and 18.

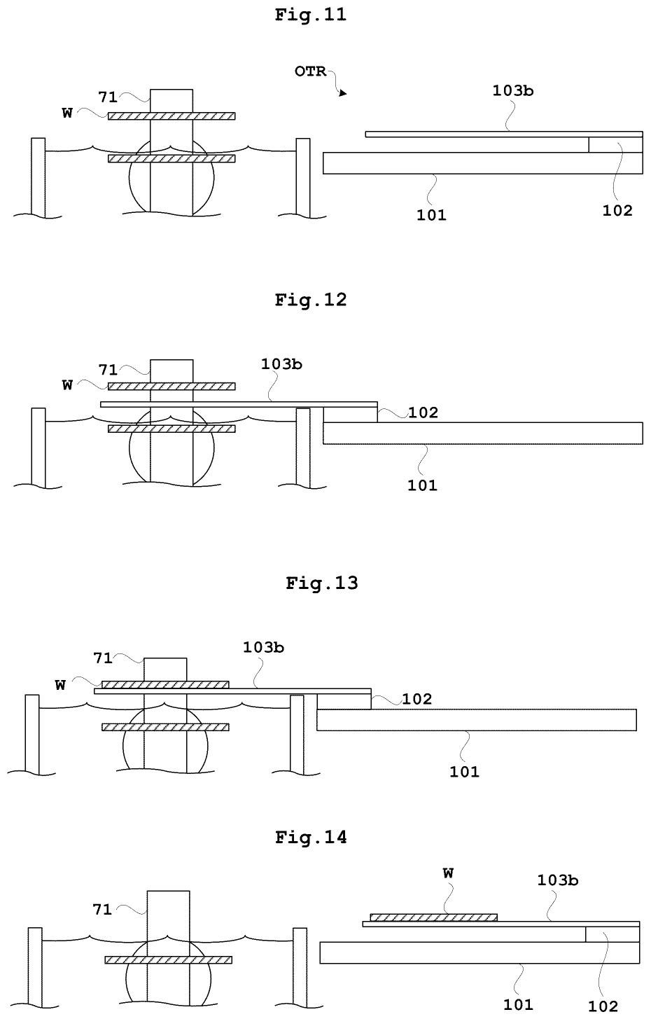

Hereinafter, a state in which the relay transfer mechanism OTR transfers the substrates W in the horizontal posture from the reverse chucks 71 in the state of FIG. 10, will be described. FIG. 11 illustrates a state when the relay transfer mechanism OTR is moved to the vicinity of the immersion tank 73 to transfer the substrates W. As illustrated in FIG. 11, the hand 103b of the relay transfer mechanism OTR includes a slide mechanism 102 that advances and retreats the hand 103b, and a support mechanism 101 that supports the slide mechanism 102. The slide mechanism 102 supports a base of the hand 103b, and can advance the hand 103b as illustrated in FIG. 12 or can retreat the hand 103b as illustrated in FIG. 14. The support mechanism 101 can reciprocate the slide mechanism 102 and the hand 103b in the Y direction. In addition, by rotating the hand 103b by 180°, the support mechanism 101 can direct the hand 103b toward the immersion tank 73 or toward the carry-out position OP.

FIG. 12 illustrates a state in which the hand 103b is inserted between the substrate W above the liquid level and the substrate W under the liquid level by the slide mechanism 102. The hand 103b is ready to acquire the substrate W in the horizontal posture by being in the state of FIG. 12. The slide mechanism 102 at this time moves from the initial position to the advanced position.

FIG. 13 illustrates a state in which the pair of reverse chucks 71 descends while maintaining the positional relationship with each other, and the substrate W above the liquid level abuts on an upper surface of the hand 103b. Since the substrate W is acquired by the hand 103b by descending the reverse chucks 71 in this manner, the relay transfer mechanism OTR can be configured without the configuration of moving the hand 103b up and down. Therefore, it is possible to provide the substrate processing system having a simple apparatus configuration and few failures.

FIG. 14 illustrates a state in which the hand 103b that has acquired the substrate W is retreated to the support mechanism 101 of the relay transfer mechanism OTR by the slide mechanism 102. Since the pair of reverse chucks 71 is in the half-opened state, the pair of reverse chucks 71 supports the substrate W held inside the liquid while allowing the substrate W to be pulled out by the hand 103b. The slide mechanism 102 at this time moves from the advanced position to the initial position.

The half-opened state of the pair of reverse chucks 71 will be described. FIG. 15 is a cross-sectional view for describing a state immediately after the substrate array is rotated by 90° as illustrated in FIG. 9. The pair of reverse chucks 71 at this time is in the closed state, and both ends of the substrate W reach the deepest portion of the V-shaped grooves. When the pair of reverse chucks 71 presses both ends of the substrate W to fix the substrate W in this manner, the substrate array does not slide off the pair of reverse chucks 71.

FIG. 16 is a cross-sectional view corresponding to FIG. 12 described above. The pair of reverse chucks 71 is in the closed state, and the hand 103b is inserted between the substrates W. Note that, in FIG. 16 and subsequent drawings of FIGS. 17 and 18, the liquid level in the immersion tank 73 is omitted.

FIG. 17 illustrates a state in which the pair of reverse chucks 71 in the closed state is slightly separated from each other to be in the half-opened state. When the pair of reverse chucks 71 gets in the half-opened state, both ends of the substrate W move from the deepest portion of the V-shaped grooves and abut on the wall portion constituting the V-shaped grooves. This state is a state in which the substrate W does not slide off the reverse chucks 71 unless the reverse chucks 71 are rotated, and also is a state in which the substrate W itself is not fixed to the reverse chucks 71. Therefore, when the pair of reverse chucks 71 is in the half-opened state, it is possible to pass one substrate W to the hand 103b at above the liquid level while holding the substrate W waiting inside the liquid. However, in the state of FIG. 17, since the hand 103b is not yet abutting on the substrate W, it is necessary to lower the substrate W with respect to the hand 103b in order to pass the substrate W to the hand 103b.

FIG. 18 is a cross-sectional view corresponding to FIG. 13 described above. In FIG. 18, the pair of reverse chucks 71 slightly descends from the state of FIG. 17 to make the substrate W abut on the hand 103b. In the state of FIG. 18, the substrate Wis placed on the hand 103b and is at a position away from the wall surface of the V-shaped grooves of the reverse chucks 71. That is, in the state of FIG. 18, the substrate W is not in contact with the reverse chucks 71. Therefore, when the slide mechanism 102 is operated to move the hand 103b in this state, the substrate W is pulled out without abutting on the reverse chucks 71.

A liquid supply nozzle 41 described in FIG. 1 supplies pure water to the substrate W pulled out by the hand 103b to bring the substrate W into a paddle state. The relay apparatus 6 of the present embodiment makes the hand 103b to transfer the substrate W in the paddle state to the carry-out position OP.

FIG. 19 illustrates a state of the substrate W in the horizontal posture acquired from the pair of reverse chucks 71. The substrate processing system of the present embodiment has a configuration related to water retention of the substrate W in the middle of the substrate transfer path in the relay apparatus 6. A shower head 69 supplies a mist of pure water to the substrate W. Since the shower head 69 is also illustrated in FIG. 1, it can also be understood with reference to FIG. 1. A tray 105 is a rectangular dish-shaped member inserted into a gap between the hand 103b and the support mechanism 101, and holds pure water supplied from the shower head 69 and dropped from the substrate W. Since the tray 105 hinders the operation of the slide mechanism 102, the tray 105 retreats in the X direction with respect to the slide mechanism 102 when the slide mechanism 102 operates as illustrated in FIGS. 12 and 13. A tray moving mechanism 108 realizes the operation of the tray 105.

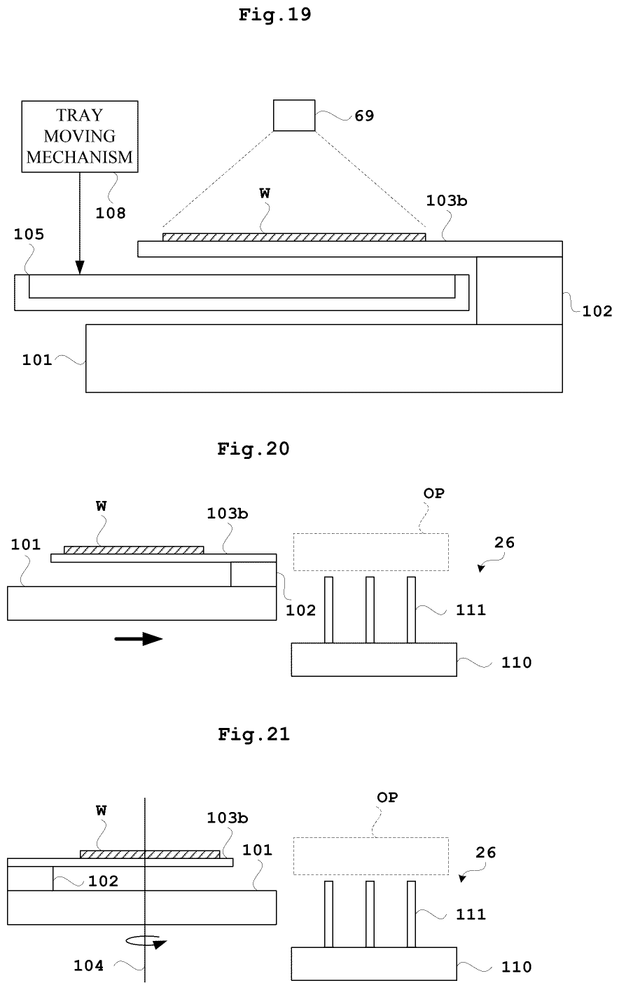

FIG. 20 illustrates a state in which the relay transfer mechanism OTR transfers the substrate W in the Y direction and moves to the vicinity of the carry-out position OP. The hand 103b at this time faces the side of the immersion tank 73 and the reverse chucks 71 while supporting the substrate W.

FIG. 21 illustrates a state when the support mechanism 101 of the relay transfer mechanism OTR then rotates by 180° about a rotation shaft 104 extending in the Z direction. By such an operation of the support mechanism 101, the hand 103b facing the immersion tank 73 side faces the carry-out position OP side.

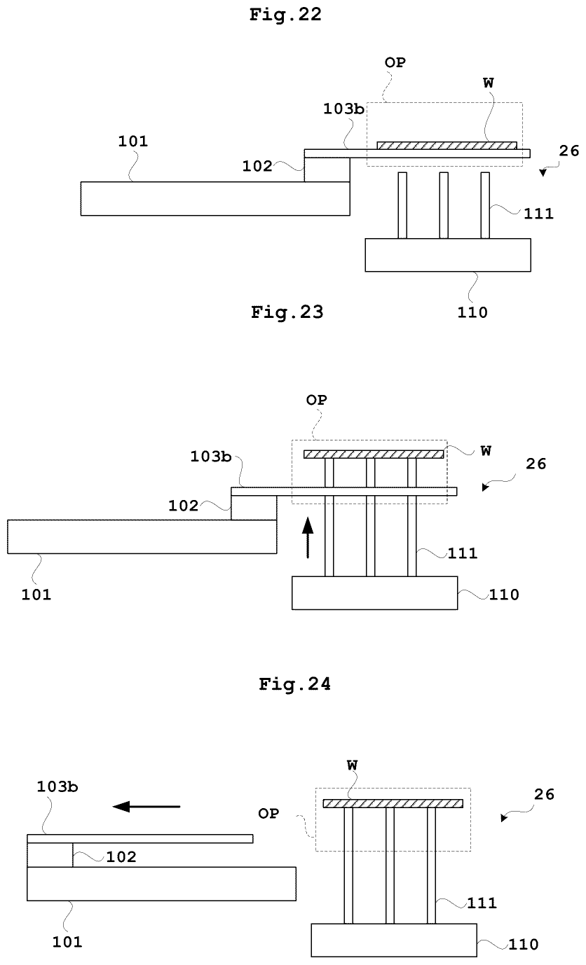

FIG. 22 illustrates a state in which the slide mechanism 102 then performs a sliding operation to move the hand 103b supporting the substrate W to the carry-out position OP. At this time, the substrate W is located at the carry-out position OP defined in the substrate processing system. In addition, the slide mechanism 102 at this time moves from the initial position to the advanced position.

Both the relay transfer mechanism OTR and a center robot CR to be described later are accessible to the carry-out position OP. The relay transfer mechanism OTR passes the substrate W to the center robot CR of the single substrate processing apparatus 2 through the carry-out position OP. The carry-out position OP includes a path including a plurality of (for example, three) support pins 111 extending in the Z direction. The support pin 111 is retractable in the Z direction. Each of the support pins 111 extends and contracts synchronously such that a distal end has the same height. A bottom plate 110 supports base end portions of the support pins 111. In FIG. 22, the distal ends of the support pin 111 are located below the carry-out position OP.

FIG. 23 illustrates a state when the support pins 111 are then extended and the substrate W supported by the hand 103b is moved to the above of the carry-out position OP. In this manner, the substrate W is held by the support pins 111 from the hand 103b.

FIG. 24 illustrates a state when the slide mechanism 102 then returns from the advanced position to the initial position, and the hand 103b is retreated from the carry-out position OP. The substrate W is supported by the support pins 111 at the carry-out position OP. As a result, the substrate W is ready to be received by the center robot CR of the single substrate processing apparatus 2.

### 11. Single Substrate Processing Apparatus: Indexer Block

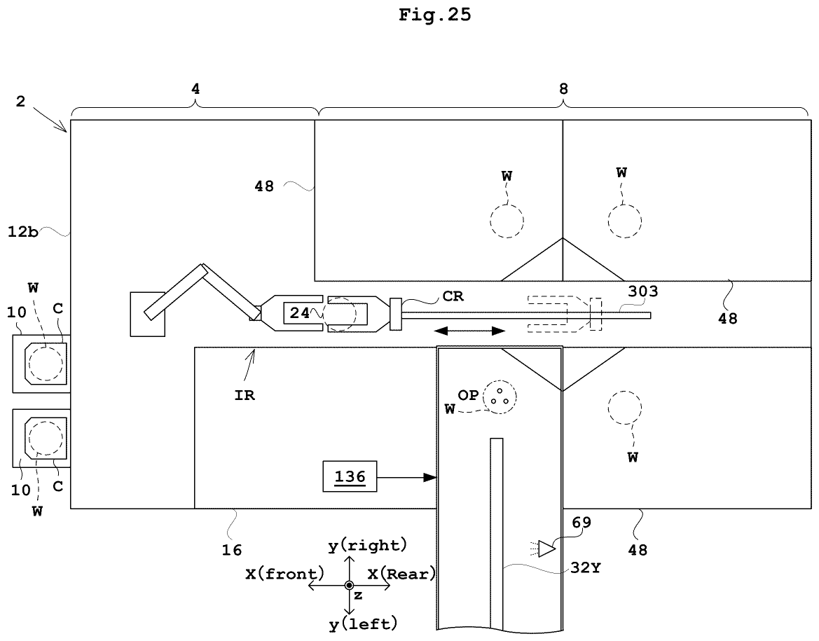

Next, a configuration of the single substrate processing apparatus 2 of the present embodiment will be described with reference to FIG. 25. The indexer block 4 includes the second load port 10 which is an entrance where the carrier C that stores the plurality of substrates W in a horizontal posture at predetermined intervals in a vertical direction is input into the block. The second load port 10 protrudes from an outer wall of the indexer block 4 extending in the width direction (Y direction).

An internal configuration of the indexer block 4 will be described. The indexer block 4 includes an indexer robot IR that transfers the substrates W in the horizontal posture one by one between the carrier C and a path 24 provided on the indexer block 4 side in the single substrate processing block 8 described later. The path 24 has a configuration on which the substrates W in the horizontal posture can be placed. The indexer robot IR is accessible between the path 24 and the carrier C placed in the second load port 10.

The indexer robot IR stores the substrates W subjected to single processing in the empty carrier C placed in the second load port 10. The indexer robot IR includes a hand including a pair of gripping bodies gripping, at a distal end, the substrate W in the horizontal posture, and an arm supporting the hand. The arm has a plurality of joints, a distal end thereof is connected to the hand, and a proximal end thereof is connected to a base of the arm provided in the indexer block 4. The indexer robot IR of the present embodiment receives the substrate W subjected to single substrate processing from the path 24 and stores the substrate W in the carrier C outside the indexer block 4.

The indexer robot IR returns the dried substrate W to the carrier C in the second load port 10.

### 12. Single Substrate Processing Apparatus: Single Substrate Processing Block

The single substrate processing block 8 is adjacent to the indexer block 4. The path 24 accessible by the indexer robot IR and the center robot CR on which the substrate W subjected to single substrate processing can be placed in the path 24 are provided at a center portion of the single substrate processing block 8 in the Y direction. The center robot CR is accessible to the carry-out position OP of the relay apparatus 6, a single substrate processing chamber 48, and the path 24. The center robot CR receives the substrates W in the horizontal posture subjected to batch processing one by one from the carry-out position OP of the relay apparatus 6 and transfers the substrate W to the single substrate processing chamber 48. The center robot CR is a substrate transfer robot that transfers the substrates W in the horizontal posture one by one, and can reciprocate in the Z direction. Therefore, as described later, the center robot CR can access both the single substrate processing chamber 48 and the carry-out position OP constituting a stacked body.

The single substrate processing chamber 48 is a drying chamber that mainly dries the substrates. The single substrate processing chamber 48 in the present embodiment is a drying chamber using a supercritical fluid. The supercritical fluid to be used can be, for example, carbon dioxide. In addition, the present invention is not limited to the configuration described above, and the single substrate processing chamber 48 may dry the substrates W by spin drying, for example. The drying chamber dries the substrates W one by one.

In addition, the apparatus of the present embodiment includes a liquid supply chamber, as a kind of the single substrate processing chamber 48, that fills the upper surface of the substrate W with liquid to make the substrate W in a paddle state. At this time, the liquid filled on the substrate W can be, for example, isopropyl alcohol (IPA). The liquid supply chamber receives the substrate W in the paddle state with pure water and discharges the substrate W in the paddle state with IPA. The discharged substrate W in the paddle state is dried by the drying chamber.

FIG. 26 is a side view of the single substrate processing apparatus 2 as viewed from the batch processing apparatus 1. As illustrated in the drawing, a single substrate processing chamber 47, the single substrate processing chamber 48, and a single substrate processing chamber 49 are stacked in the Z direction to form a stacked body. That is, the single substrate processing block 8 is provided with a lower stage region, a middle stage region, and an upper stage region. The single substrate processing chamber 47 is provided in the lower stage region. The single substrate processing chamber 48 is provided in the middle stage region. The single substrate processing chamber 49 is provided in the upper stage region.

The carry-out position OP is located in the middle stage region of the single substrate processing block 8. The single substrate processing chamber 47 in the lower stage region is provided below the carry-out position OP. The single substrate processing chamber 49 in the upper stage region is provided above the carry-out position OP. Therefore, the carry-out position OP is provided in place of the single substrate processing chamber 48 in the middle stage region, in the stacked body configured by arranging, in the Z direction, the single substrate processing chamber 47, the single substrate processing chamber 48, and the single substrate processing chamber 49.

FIG. 25 describes the middle stage region of the single substrate processing block 8. Three single substrate processing chambers 48 are provided in the middle stage region. Therefore, the single substrate processing block 8 includes a first stacked body to which the first single substrate processing chamber 48 belongs, a second stacked body to which the second single substrate processing chamber 48 belongs, and a third stacked body to which the third single substrate processing chamber 48 belongs. In addition, the single substrate processing chamber 49 and the single substrate processing chamber 47 are provided above and below the carry-out position OP. Therefore, a total of 11 single substrate processing chambers are provided in the single substrate processing block 8.

As illustrated in FIG. 26, a shielding plate 16 is a part of a wall surface of the single substrate processing apparatus 2. The shielding plate 16 is provided in a middle stage region of the single substrate processing block 8, and closes an opening generated between the carry-out position OP and the indexer block 4. By providing the shielding plate 16 adjacent to the indexer block 4, the relay apparatus 6 can be provided close to the center robot CR. In this way, when the center robot CR acquires the substrate W at the carry-out position OP, it is not necessary for the center robot CR to greatly move in the front-rear direction.

Note that the hand of the center robot CR can move in the Z direction while maintaining the posture of the substrate W. With this configuration, the center robot CR can transfer the substrate W at the carry-out position OP to the single substrate processing chamber 49 in the upper stage region and the single substrate processing chamber 47 in the lower stage region. By providing the carry-out position OP in the middle stage region of the single substrate processing block 8, the carry-out position OP can be disposed in the vicinity of the upper stage region. Similarly, the carry-out position OP is disposed in the vicinity of the lower stage region. Therefore, the moving distance of the substrate W in the Z direction at the carry-out position OP is short for both the upper stage region and the lower stage region.

### 13. Single Substrate Processing Apparatus: Center Robot

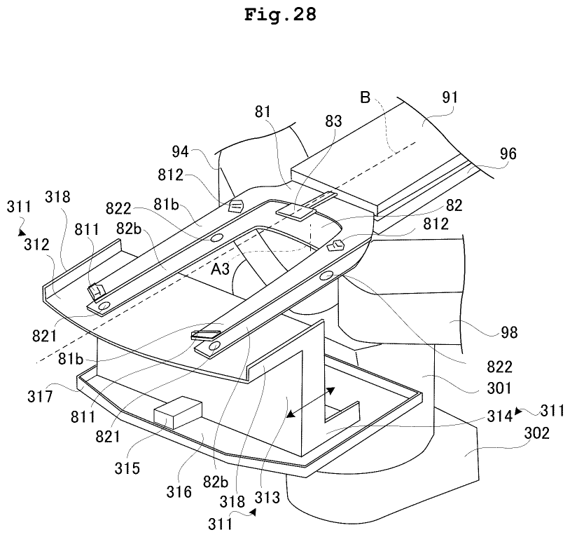

FIG. 27 describes a specific configuration of the center robot CR. The center robot CR of the present embodiment has two hands and a drive mechanism that independently drives the two hands. The two hands are arranged vertically, the upper hand is for dry substrate transfer, and the lower hand is for paddle-state wet substrate transfer. FIG. 27 is a plan view of the center robot CR, so that only the upper hand of the center robot CR can be visually observed. A state in which the two hands are provided in the center robot CR can be understood with reference to the perspective view of FIG. 28.

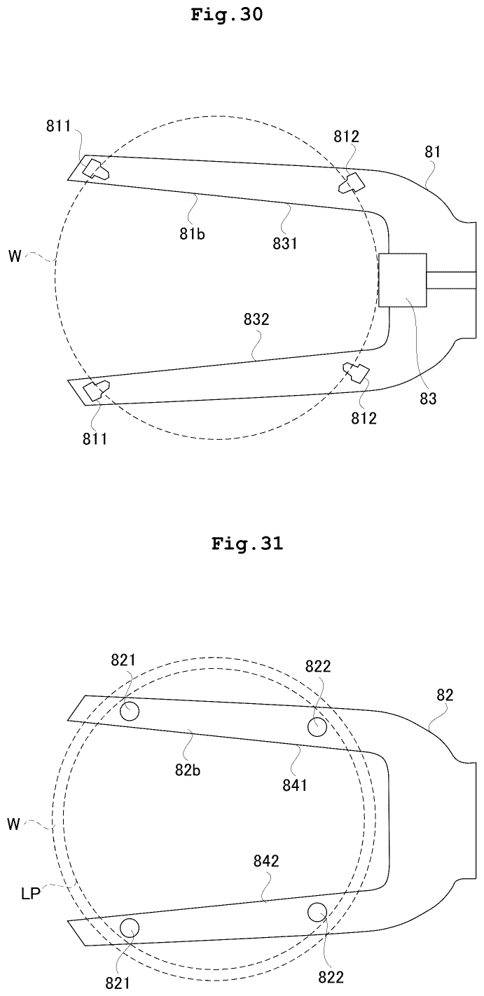

The hand that transfers the dry substrate is referred to as a dry substrate hand 81. The dry substrate hand 81 can grip the dry substrate in the horizontal posture. The dry substrate hand 81 has a flat shape extending on a horizontal plane, and includes a first branch blade 81b including a base and two flat bars 831 and 832 extending from the base (see FIGS. 27 and 30). The first branch blade 81b corresponds to a first blade of the present invention. A pair of distal end guides 811 is provided at distal ends of the first branch blade 81b, and a pair of proximal end guides 812 is provided at proximal ends of the first branch blade 81b. The distal end guides 811 and the proximal end guides 812 are provided on an upper surface of the first branch blade 81b. One distal end guide 811 and one proximal end guide 812 are provided in each of the flat bars 831 and 832 of the first branch blade 81b.

The pair of distal end guides 811 is provided at a distal end portion of the first branch blade 81b, and is capable of bringing a substrate end portion into contact with the distal end guides 811. In addition, the pair of proximal end guides 812 is provided at a proximal end portion of the first branch blade 81b, and is capable of bringing the substrate end portion into contact with the proximal end guides 812.

A hand pusher 83 that can be abutted on a side surface of the substrate W is provided at the base of the first branch blade 81b (see FIGS. 27 and 30). The hand pusher 83 corresponds to a pusher of the present invention. The hand pusher 83 includes a drive portion at a base thereof, and moves forward and backward in an extending direction (extending direction B) of the first branch blade 81b. When the hand pusher 83 gets in an extended state with the substrate W placed on the dry substrate hand 81, the substrate W is gripped by the dry substrate hand 81. When the hand pusher 83 gets in a contracted state from this state, the gripping state of the dry substrate hand 81 is released. The hand pusher 83 is disposed at the proximal end portion of the first branch blade 81b and at a position sandwiched between the pair of proximal end guides 812, and can grip the substrate W in cooperation with the distal end guides 811 by pressing the end portion of the substrate W.

A hand that supports the substrate W in the paddle state is referred to as a wet substrate hand 82. The wet substrate hand 82 can support the liquid-filled substrate and is provided below the dry substrate hand 81. Similarly to the dry substrate hand 81, the wet substrate hand 82 has a flat shape extending on a horizontal plane, and includes a second branch blade 82b including a base and two flat bars 841 and 842 extending from the base (see FIG. 31). A pair of distal end protrusions 821 is provided at distal ends of the second branch blade 82b, and a pair of proximal end protrusions 822 is provided at proximal ends of the second branch blade 82b. The distal end protrusions 821 and the proximal end protrusions 822 are provided on an upper surface of the second branch blade 82b. One distal end protrusion 821 and one proximal end protrusion 822 are provided in each of the flat bars 841 and 842 of the second branch blade 82b.

The wet substrate hand 82 can support the substrate W in the paddle state with four protrusions on the upper surface of the second branch blade 82b. The distal end protrusions 821 are provided at the distal end portion of the second branch blade 82b, and can abut on a predetermined portion of a lower surface of the liquid-filled substrate W from which the substrate end portion is removed. The proximal end protrusions 822 are provided at the proximal end portion of the second branch blade 82b, and can abut on the above-described predetermined portion of the lower surface of the liquid-filled substrate W. The predetermined portion will be described later.

A drive mechanism for driving the dry substrate hand 81 in the horizontal direction will be described. As illustrated in FIG. 27, the dry substrate hand 81 is connected to a first distal end arm 91 extending in the extending direction B. The first distal end arm 91 is connected to a first proximal end arm 94 via a first relay arm 92. The first relay arm 92 extends in a direction intersecting the extending direction B and parallel to the horizontal plane. The first proximal end arm 94 also extends in a direction intersecting the extending direction B and parallel to the horizontal plane.

The first distal end arm 91 is rotatable with respect to the first relay arm 92. That is, the first distal end arm 91 and the first relay arm 92 constitute a joint having a vertical axis as a rotation axis. Similarly, the first relay arm 92 is rotatable with respect to the first proximal end arm 94. That is, the first relay arm 92 and the first proximal end arm 94 constitute a joint having a vertical axis as a rotation axis.

The first proximal end arm 94 is connected to a robot base 301. The first proximal end arm 94 is rotatable with respect to the robot base 301. That is, the first proximal end arm 94 and the robot base 301 constitute a joint having a vertical axis as a rotation axis.

The first distal end arm 91, the first relay arm 92, and the first proximal end arm 94 can advance and retreat the dry substrate hand 81 in the extending direction B with respect to the robot base 301 by performing synchronous rotational operation using the joints provided to one another. That is, the first distal end arm 91, the first relay arm 92, and the first proximal end arm 94 constitute a first moving mechanism of the present invention that movably supports the dry substrate hand 81.

A drive mechanism for driving the wet substrate hand 82 in the horizontal direction will be described. As illustrated in FIG. 28, the wet substrate hand 82 is connected to a second distal end arm 96 extending in the extending direction B. The second distal end arm 96 is connected to a second proximal end arm 98 (see FIGS. 27 and 28) via a second relay arm 97 (see FIG. 27). The second relay arm 97 extends in a direction parallel to the horizontal plane. The second proximal end arm 98 also extends in a direction parallel to the horizontal plane.

The second distal end arm 96 is rotatable with respect to the second relay arm 97. That is, the second distal end arm 96 and the second relay arm 97 constitute a joint having a vertical axis as a rotation axis. Similarly, the second relay arm 97 is rotatable with respect to the second proximal end arm 98. That is, the second relay arm 97 and the second proximal end arm 98 constitute a joint having a vertical axis as a rotation axis.

The second proximal end arm 98 is connected to the robot base 301 similarly to the first proximal end arm 94. The second proximal end arm 98 is rotatable with respect to the robot base 301. That is, the second proximal end arm 98 and the robot base 301 constitute a joint having a vertical axis as a rotation axis.

The second distal end arm 96, the second relay arm 97, and the second proximal end arm 98 can advance and retreat the wet substrate hand 82 in the extending direction B with respect to the robot base 301 by performing synchronous rotational operation using the joints provided to one another. That is, the second distal end arm 96, the second relay arm 97, and the second proximal end arm 98 constitute a second moving mechanism of the present invention that movably supports the wet substrate hand 82.

The robot base 301 corresponds to a base member of the present invention. The robot base 301 supports the first moving mechanism of the present invention including the first distal end arm 91, the first relay arm 92, and the first proximal end arm 94, and supports the second moving mechanism of the present invention including the second distal end arm 96, the second relay arm 97, and the second proximal end arm 98.

A lifting/lowering rotation mechanism 302 illustrated in FIG. 28 supports the robot base 301 in a liftable/lowerable manner and in a rotatable manner about the vertical axis. The lifting/lowering rotation mechanism 302 moves the dry substrate hand 81 up and down and turns the dry substrate hand 81. In addition, the lifting/lowering rotation mechanism 302 can also move the wet substrate hand 82 up and down and turn the wet substrate hand 82. Therefore, the dry substrate hand 81 and the wet substrate hand 82 of the present embodiment move up and down and turn while maintaining a mutual positional relationship.

FIG. 25 illustrates a slide mechanism 303 that supports the lifting/lowering rotation mechanism 302. The slide mechanism 303 includes a rail extending in the front-rear direction X, and is configured to advance and retreat the lifting/lowering rotation mechanism 302 in the front-rear direction X. Since the center robot CR includes the slide mechanism 303, the center robot CR can advance and retreat the dry substrate hand 81 and the wet substrate hand 82 in the front-rear direction X.

FIG. 28 also describes two vats included in the center robot CR. That is, the center robot CR includes a fixing vat 316 and a moving vat 311 on the assumption that the liquid scatters from the substrate W in the paddle state. The fixing vat 316 is fixed to the robot base 301. Therefore, the fixing vat 316 is displaced in accordance with the ascend/descend movement and the advance/retreat movement of the robot base 301. The fixing vat 316 has a flat shape extending in a horizontal plane, and includes a wall portion 317 edging an end portion. The wall portion 317 prevents a liquid pool generated when the fixing vat 316 receives liquid from being dropped below the fixing vat 316. The fixing vat 316 is provided below the wet substrate hand 82, and is configured to collect the liquid that has dropped from the wet substrate hand 82.

The fixing vat 316 is supported by the robot base 301 below the wet substrate hand 82, and is configured to collect the liquid that has dropped from the wet substrate hand 82.

The moving vat 311 includes a top plate portion 312, a base body 314, and a coupling portion 313 that couples the top plate portion 312 and the base body 314. The top plate portion 312 has a flat shape extending in a horizontal plane, and includes wall portions 318 at both end portions. The wall portions 318 prevent a liquid pool generated when the top plate portion 312 of the moving vat 311 receives liquid from being dropped below the top plate portion 312. The top plate portion 312 does not have wall portions at both ends in the extending direction B of the hand. With such a configuration, the wet substrate hand 82 and the top plate portion 312 do not interfere with each other. The wall portions 318 are provided at both ends of the top plate portion 312 in the width direction orthogonal to the extending direction B of the hand and the vertical direction.

The moving vat 311 is provided between the wet substrate hand 82 and the fixing vat 316, and is configured to receive the liquid that has dropped from the wet substrate hand 82 and guide the liquid to the fixing vat 316. The moving vat 311 corresponds to a second vat of the present invention.

The base body 314 of the moving vat 311 is supported by the fixing vat 316. The base body 314 forms a bottom surface of the moving vat 311, and can advance and retreat in the extending direction B of the hand with respect to the fixing vat 316. Therefore, the moving vat 311 can advance and retreat in the extending direction B of the vat with respect to the fixing vat 316.

The advance/retreat mechanism 315 is a drive mechanism provided on an upper surface of the fixing vat 316, and includes a rail extending in the extending direction B of the hand. The base body 314 is connected to the advance/retreat mechanism 315, so that the moving vat 311 can advance and retreat in the extending direction B of the hand as indicated by an arrow in FIG. 28.

The advance/retreat mechanism 315 is configured to advance and retreat the moving vat 311 in the horizontal direction with respect to the fixing vat 316 and the robot base 301. The advance/retreat mechanism 315 corresponds to a second vat advance/retreat mechanism.

The top plate portion 312 of the moving vat 311 is provided below the wet substrate hand 82 and is configured to receive the liquid that has been dropped from the wet substrate hand 82. The liquid pool generated in the top plate portion 312 is guided to the wall portions 318 and drips onto the fixing vat 316.

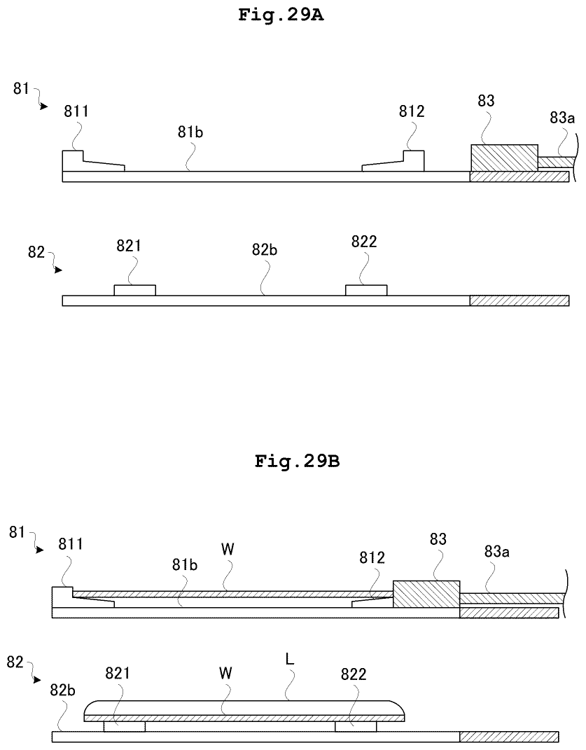

FIG. 29A illustrates cross sections of the dry substrate hand 81 and the wet substrate hand 82. The dry substrate hand 81 includes the distal end guides 811 at the distal end portion and the proximal end guides 812 at the proximal end portion. When the dry substrate hand 81 is in the opened state, the hand pusher 83 is in the contracted state, and the dry substrate hand 81 is configured to receive the substrate W. A hand pusher driving mechanism 83a makes the hand pusher 83 advance and retreat in the extending direction B of the hand.

Meanwhile, the wet substrate hand 82 includes the distal end protrusions 821 at the distal end portion and the proximal end protrusions 822 at the proximal end portion. Since the wet substrate hand 82 in FIG. 29A does not support the substrate W, it is configured to receive the substrate W.

FIG. 29B is a view similar to FIG. 29A, but illustrates a state in which the dry substrate hand 81 has received the dry substrate. The dry substrate hand 81 presses the substrate W against the distal end guides 811 by pressing the hand pusher 83 against the end side of the substrate W. In this manner, the substrate W is sandwiched and gripped between the hand pusher 83 in the closed state and the distal end guides 811.

Meanwhile, the wet substrate hand 82 can support the liquid-filled substrate W. The wet substrate hand 82 supports the substrate W from the lower surface via the distal end protrusions 821 and the proximal end protrusions 822. Since the wet substrate hand 82 at this time does not include a member abutting on the end side of the substrate W, a liquid L filled on the substrate W cannot drip down along the wet substrate hand 82.

FIG. 30 is a plan view of the dry substrate hand 81 in the gripped state (closed state). The dry substrate hand 81 presses one end side of the substrate W by the hand pusher 83 and presses the other end side of the substrate W against the distal end guides 811. The proximal end guides 812 support, together with the distal end guides 811, the end side of the substrate W when the hand pusher 83 is in the contracted state and the dry substrate hand 81 is in the opened state.

FIG. 31 is a plan view of the wet substrate hand 82 that supports the liquid-filled substrate W. The distal end protrusions 821 and the proximal end protrusions 822 included in the wet substrate hand 82 at this time abut on the substrate W at a predetermined portion LP avoiding the end side of the substrate W.

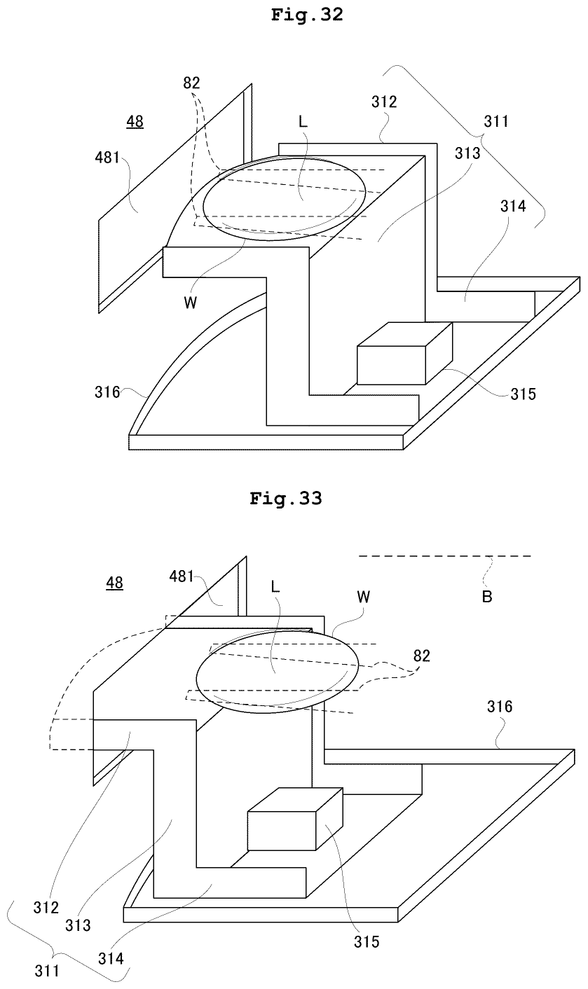

Next, the operation of the moving vat 311 will be described. FIG. 32 illustrates a state in which the liquid-filled substrate W supported by the wet substrate hand 82 is located above the top plate portion 312 of the moving vat 311. Even if the liquid L filled on the substrate W drops from the substrate W at this time point, the liquid Lis surely received by the moving vat 311. In FIG. 32, the wet substrate hand 82 faces a carry-in port 481 of the substrate W included in the single substrate processing chamber 48. In FIG. 32, the wet substrate hand 82 is about to carry the substrate W into the single substrate processing chamber 48 through the carry-in port 481. The single substrate processing chamber 48 at this time may be either a drying processing chamber or a liquid supply chamber, and the liquid filled on the substrate W may be either pure water or IPA.

FIG. 33 illustrates a state in which the moving vat 311 moves in the extending direction B of the wet substrate hand 82 before the wet substrate hand 82 is inserted into the carry-in port 481. By this movement, the top plate portion 312 of the moving vat 311 protrudes from the fixing vat 316. Then, a distal end of the top plate portion 312 enters the carry-in port 481 of the single substrate processing chamber 48. Such an operation of the moving vat 311 is realized by the advance/retreat mechanism 315 provided in the fixing vat 316. Even if the liquid L filled on the substrate W drops from the substrate W at this time point, the liquid L is surely received by the moving vat 311 or the fixing vat 316.

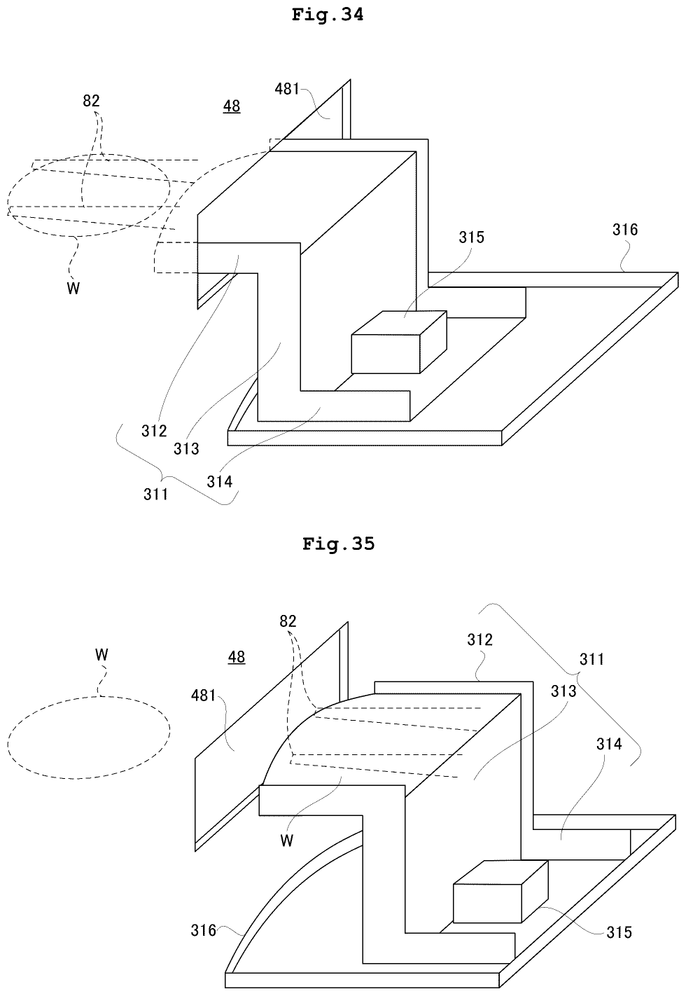

FIG. 34 illustrates a state in which the wet substrate hand 82 introduces the liquid-filled substrate W through the carry-in port 481 to the inside of the single substrate processing chamber 48. The wet substrate hand 82 moves the liquid-filled substrate W to a further deep portion of the single substrate processing chamber 48 beyond the moving vat 311 protruding toward the carry-in port 481. Thereafter, the substrate W is passed to a support member of the substrate W such as a pin or a chuck included in the single substrate processing chamber 48. Even if the liquid L filled on the substrate W drops from the substrate W at this time point, the liquid L is surely received by the moving vat 311 or inside the single substrate processing chamber 48.

As described above, when the liquid-filled substrate W is introduced to the inside of the single substrate processing chamber 48, since the distal end of the moving vat 311 is located inside the carry-in port 481, the liquid L filled on the substrate W cannot scatter from the gap between the fixing vat 316 and the carry-in port 481 in any way. This is because the moving vat 311 is located so as to bridge between the inside of the single substrate processing chamber 48 and the fixing vat 316, and the liquid L is received by the moving vat 311.

After the single substrate processing chamber 48 receives the liquid-filled substrate W, the moving vat 311 and the wet substrate hand 82 are retreated from the single substrate processing chamber 48. At this time, if the wet substrate hand 82 is retreated before the moving vat 311, the liquid L adhering to the wet substrate hand 82 cannot scatter from the gap between the fixing vat 316 and the carry-in port 481. This is because the moving vat 311 is located so as to bridge between the inside of the single substrate processing chamber 48 and the fixing vat 316, and the liquid L is received by the moving vat 311.

FIG. 35 illustrates a state when the liquid-filled substrate W is carried out from the liquid feeding chamber which is a kind of the single substrate processing chamber 48. At this time, the liquid filled on the substrate is IPA. In FIG. 35, the wet substrate hand 82 faces the carry-in port 481 of the substrate W included in the single substrate processing chamber 48.

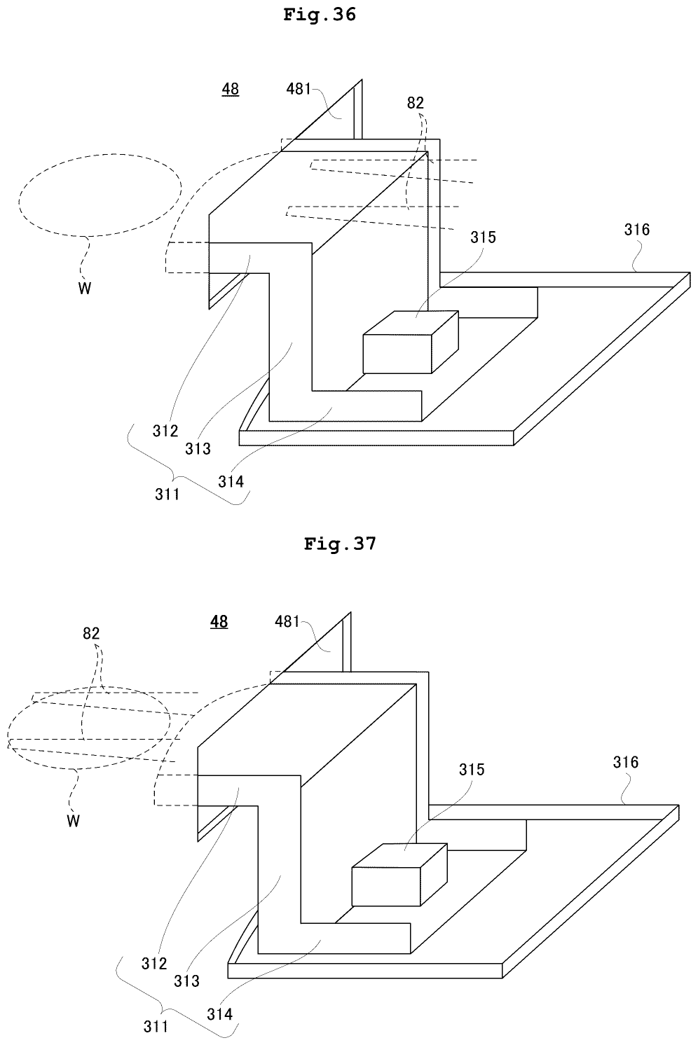

FIG. 36 illustrates a state in which the moving vat 311 moves in the extending direction B of the wet substrate hand 82 before the wet substrate hand 82 is inserted into the carry-in port 481. By this movement, the top plate portion 312 of the moving vat 311 protrudes from the fixing vat 316. Then, the distal end of the top plate portion 312 enters the carry-in port 481 of the single substrate processing chamber 48.

FIG. 37 illustrates the subsequent state. The wet substrate hand 82 receives the liquid-filled substrate W located at the further deep portion of the single substrate processing chamber 48 beyond the moving vat 311 protruding toward the carry-in port 481.

After the wet substrate hand 82 receives the liquid-filled substrate W, the moving vat 311 and the wet substrate hand 82 are retreated from the single substrate processing chamber 48. At this time, if the wet substrate hand 82 is retreated before the moving vat 311, the liquid L filled on the substrate W cannot scatter from the gap between the fixing vat 316 and the carry-in port 481. This is because the moving vat 311 is located so as to bridge between the inside of the single substrate processing chamber 48 and the fixing vat 316, and the liquid L is received by the moving vat 311.

### 14. Other Configurations

The substrate processing system includes a control unit 131 related to control of the batch processing apparatus 1, a control unit 132 related to control of the single substrate processing apparatus 2, and a control unit 136 related to control of the relay apparatus 6. FIG. 1 can be referred to for each of the control units. In addition, although not illustrated in FIG. 1, a storage unit corresponding to each control unit is provided in the substrate processing system. The control unit 131, the control unit 132, and the control unit 136 are each configured by, for example, a central processing unit (CPU). A specific configuration of each control unit is not limited, and for example, the control units may be configured by a single processor, or the control units may each be configured by an individual processor. In addition, the control related to the batch processing apparatus 1 may be configured by a plurality of processors, and this circumstance is similar in the single substrate processing apparatus 2 and the relay apparatus 6.

Examples of the control related to the control unit 131 include control related to the carrier transfer mechanism 11, the handling robot HTR, the HVC posture converting unit 23, the pusher mechanism 25, the substrate transfer mechanism WTR, and the batch processing units BPU1 to BPU6. Examples of the control related to the control unit 132 include control related to the center robot CR, the single substrate processing chamber 48, and the indexer robot IR. In addition, examples of the control related to the control unit 136 include control related to the reverse chuck 71, the relay transfer mechanism OTR, and a pure water supply apparatus coupled to the shower head 69.

That is, the control unit 132 controls the center robot CR to receive the liquid-filled substrate W by the wet substrate hand 82 and transfer the substrate W to the drying chamber. The control unit 132 controls the drying chamber to dry the substrate W. The control unit 132 controls the center robot CR to receive, by the dry substrate hand 81, the substrate dried in the drying chamber and transfer the substrate to the indexer robot IR. Then, the control unit 132 controls the indexer robot IR to return the dried substrate W to the carrier C.

The storage unit stores programs, parameters, and the like related to the control. The storage units may be configured by a single device or may be configured by an individual device corresponding to the respective one of the control units. In addition, the substrate processing system of the present embodiment has no particular limitation on the configuration of the device that realizes the storage unit.

### 15. Flow of Substrate Processing

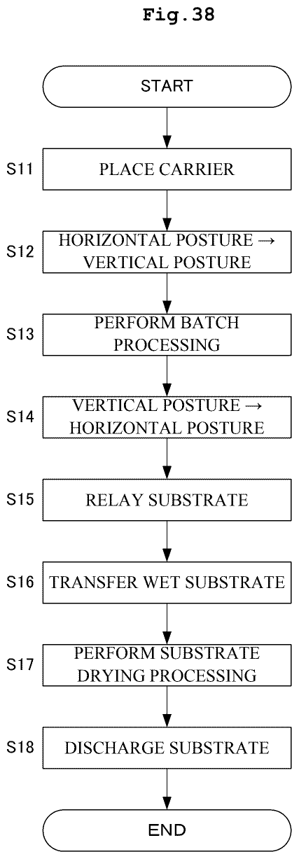

Next, a flow of the substrate processing using the substrate processing system of the present embodiment will be described. FIG. 38 is a flowchart indicating an operation of the substrate processing system of the present embodiment.

Step S11: The carrier C storing the unprocessed substrate W is placed in the first load port 9. The carrier C is transferred to the carrier placement shelf 13a by the carrier transfer mechanism 11. The handling robot HTR extracts the substrate array from the carrier C and transfers the substrate array to the HVC posture converting unit 23.

Step S12: The HVC posture converting unit 23 inclines the substrate array constituted by the substrates W in the horizontal posture by 90°. As a result, the posture of the substrates W constituting the substrate array is converted from the horizontal posture to the vertical posture. The pusher mechanism 25 receives the substrate array subjected to posture conversion from the HVC posture converting unit 23 and passes the substrate array to the substrate transfer mechanism WTR. The substrate transfer mechanism WTR passes the received substrate array to, for example, the lifter LF6 of the batch processing unit BPU6.

Step S13: The batch processing unit BPU6 lowers the lifter LF6 to start the batch-type chemical liquid processing. The substrate array on which the batch processing has been completed is transferred, this time, to the lifter LF1 of the batch processing unit BPU1 by the substrate transfer mechanism WTR. The batch processing unit BPU1 lowers the lifter LF1 to start the batch-type rinse processing. The substrate array on which the batch processing has been completed is transferred, this time, to the immersion tank 73 by the substrate transfer mechanism WTR. The substrate array at this time is constituted by the substrates W in the vertical posture, and is in a state of being held by the pair of reverse chucks 71.

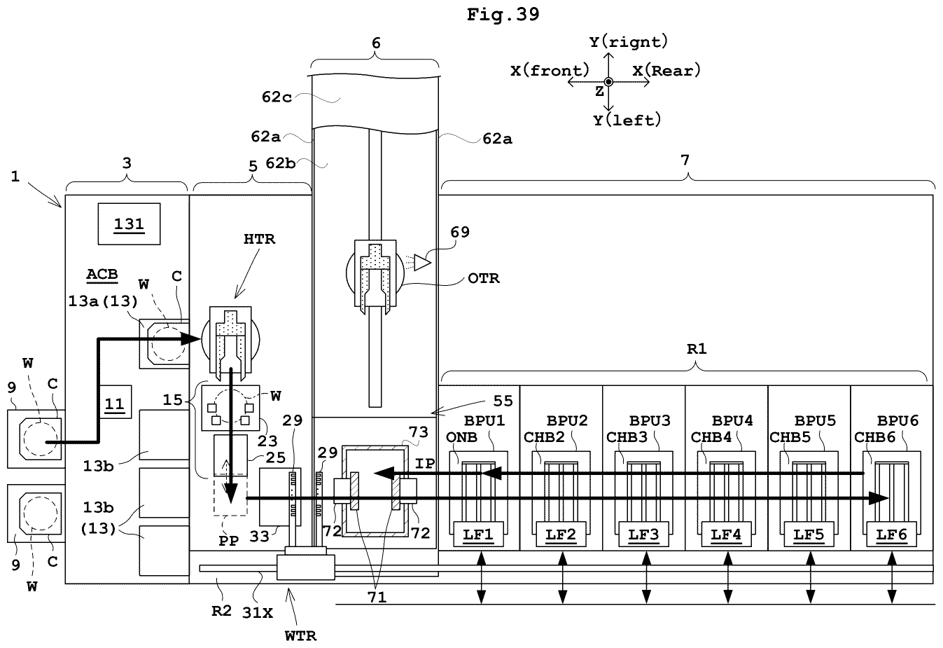

Step S14: The pair of reverse chucks 71 inclines the substrate array by 90° in the immersion tank 73. As a result, the posture of the substrates W constituting the substrate array is converted from the vertical posture to the horizontal posture. FIG. 39 illustrates a transfer path of the substrate array from step S11 to step S14. These steps are a process of collectively transferring the plurality of substrates W as the substrate array.

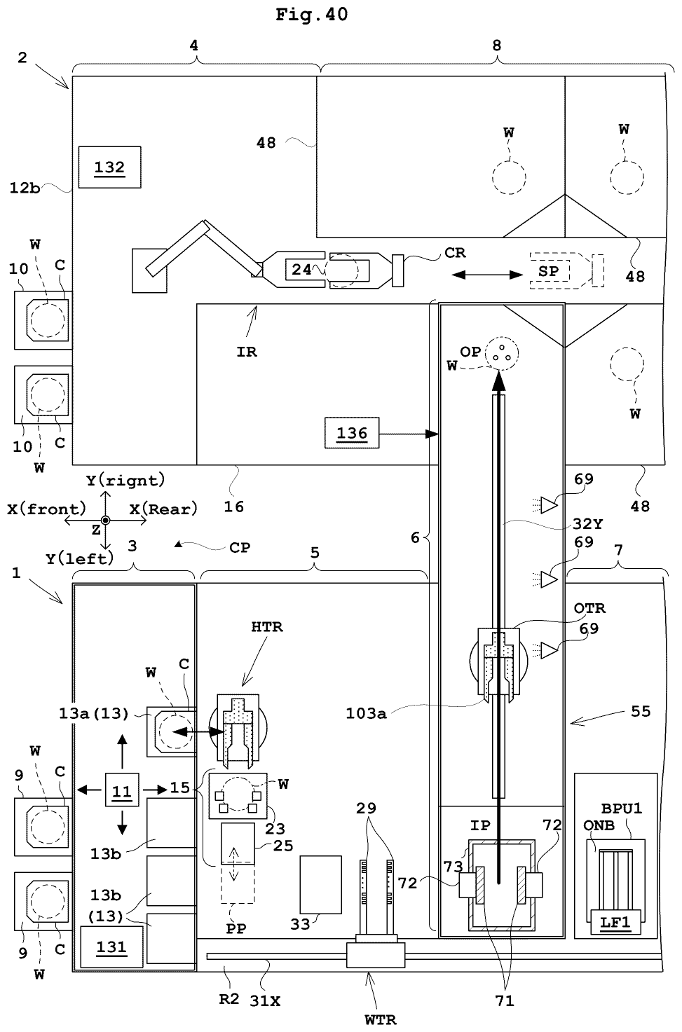

Step S15: The substrates W in the horizontal posture are transferred one by one from the immersion tank 73 to the carry-out position OP by the relay transfer mechanism OTR. Pure water is filled on the substrate W at this time, and the substrate W moves from the immersion tank 73 to the carry-out position OP in the paddle state. FIG. 40 illustrates the transfer path of the substrate W in this step. In this manner, the substrate W is transferred from the batch processing apparatus 1 to the single substrate processing apparatus 2 through the relay apparatus 6.

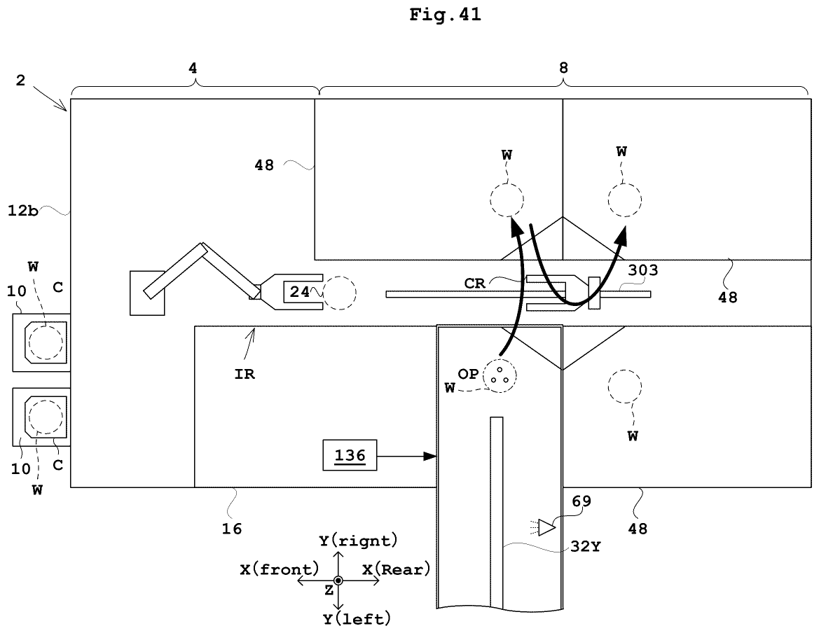

Step S16: The substrate W in the paddled state by pure water is transferred from the carry-out position OP to the single substrate processing chamber 48 by the center robot CR. Specifically, the center robot CR receives the substrate W on which pure water is filled from the carry-out position OP, and transfers the substrate W to the liquid supply chamber which is a kind of the single substrate processing chamber 48. Then, the center robot CR receives the substrate W on which IPA is filled in the liquid supply chamber, from the liquid supply chamber, and transfers the substrate W to the drying processing chamber which is a kind of the single substrate processing chamber 48. FIG. 41 illustrates the transfer path of the substrate W in this step.

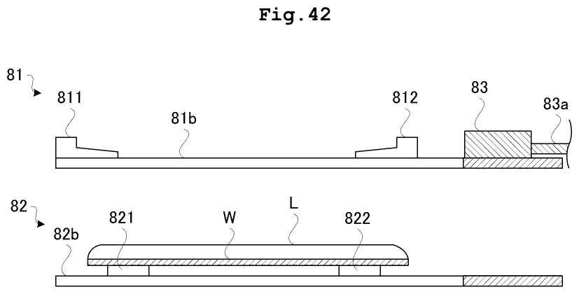

The transfer of the substrate in this step is performed using the wet substrate hand 82 in the center robot CR. As illustrated in FIG. 42, the wet substrate hand 82 can support and transfer the substrate W on which pure water or IPA is filled by the distal end protrusions 821 and the proximal end protrusions 822 provided at positions avoiding the end sides of the substrate W.

Step S17: The substrate W transferred to the single substrate processing chamber 48 is subjected to the substrate drying processing.

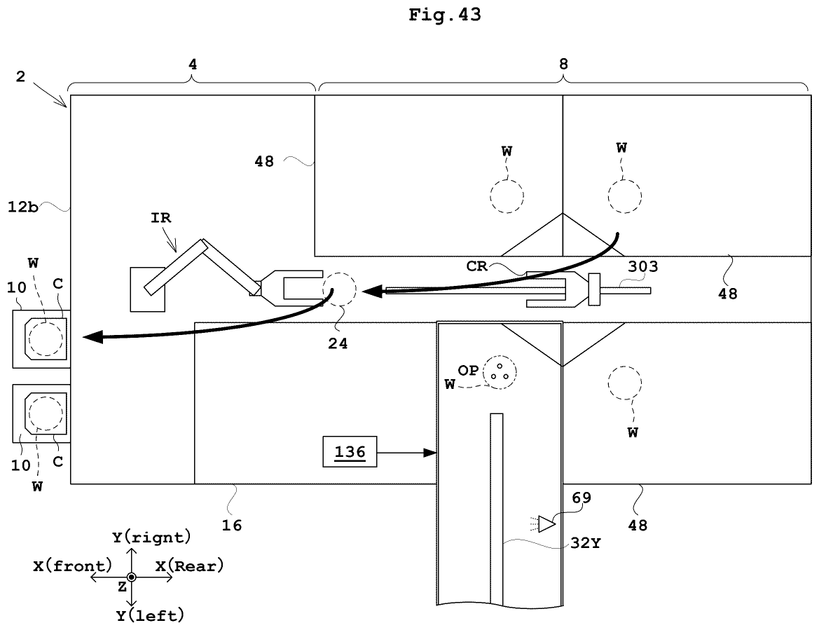

Step S18: The substrate W subjected to the drying processing by the single substrate processing chamber 48 is transferred to the path 24 by the center robot CR. The indexer robot IR receives the substrate W transferred to the path 24 and stores the substrate W in the carrier C placed in the second load port 10. In this manner, the substrate processing according to the present embodiment is completed. FIG. 43 illustrates the transfer path of the substrate W in this step.

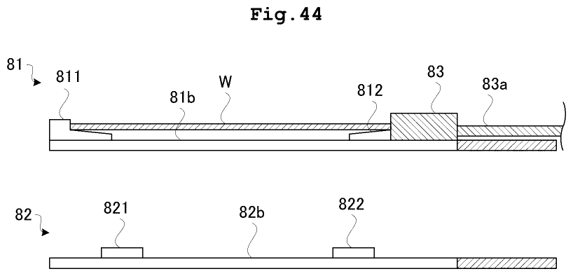

In this step, the center robot CR performs the substrate transfer from the single substrate processing chamber 48 to the path 24 using the dry substrate hand 81. As illustrated in FIG. 44, the dry substrate hand 81 transfers the substrate W while gripping the substrate W by the distal end guides 811 and the hand pusher 83. At this time, since the substrate W is surely gripped by the dry substrate hand 81, the substrate can be transferred at high speed.

### 16. Effects of Present Invention

As described above, according to the configuration of the present invention, the dry substrate hand 81 includes the first branch blade 81b, the pair of proximal end guides 812 provided at the proximal end portion of the first branch blade 81b and in contact with the substrate end portion, the pair of distal end guides 811 provided at the distal end portion of the first branch blade 81b and in contact with the substrate end portion, and the hand pusher 83 for substrate gripping that is disposed at a position at the proximal end portion of the first branch blade 81b and sandwiched between the pair of proximal end guides 812 and is capable of gripping the substrate W in cooperation with the distal end guides 811 by coming into contact with the end side of the substrate W and pressing the substrate W toward the distal end guides 811. With this configuration, it is possible to provide a substrate transfer apparatus capable of performing transfer at high speed in a state where the substrate W is surely gripped.

In addition, according to the above configuration, the wet substrate hand 82 includes the second branch blade 82b, the pair of proximal end protrusions 822 provided at the proximal end portion of the second branch blade 82b and in contact with the lower surface of the substrate W to support the substrate W, and the pair of distal end protrusions 821 provided at the distal end portion of the second branch blade 82b and in contact with the lower surface of the substrate W to support the substrate W. With this configuration, the liquid filled on the substrate does not drip down along the member by pressing the member against the end side of the substrate W.

According to the above configuration, the dry substrate hand 81 is provided separately from the wet substrate hand 82. As described above, the configuration including the individual hands according to the wet state of the substrate W prevents the dry substrate from being transferred by the wet hand. According to the configuration of the present invention, it is possible to transfer the substrate W while the dry state of the substrate is surely maintained.

According to the above configuration, the wet substrate hand 82 is provided below the dry substrate hand 81. With this configuration, the liquid dripping from the wet substrate hand 82 is not transmitted to the dry substrate hand 81. This is because the dry substrate hand 81 is provided above the wet substrate hand 82.

According to the above configuration, there are provided the fixing vat 316 that is supported by the robot base 301 below the wet substrate hand 82 and collects the liquid that has dropped from the wet substrate hand 82, and the moving vat 311 that is provided between the wet substrate hand 82 and the fixing vat 316 and receives the liquid that has dropped from the wet substrate hand 82 and guides the liquid to the fixing vat 316. With this configuration, the liquid dripping from the wet substrate hand 82 is collected in the fixing vat 316. When the moving vat 311 follows the advance/retreat movement of the wet substrate hand 82, the liquid filled on the substrate W can be received by the moving vat 311 regardless of the position of the wet substrate hand 82. Therefore, according to the above configuration, it is possible to provide a substrate transfer apparatus capable of suppressing scattering of liquid.

According to the above configuration, the control unit 132 controls the center robot CR to receive the liquid-filled substrate W by the wet substrate hand 82 and transfer the substrate W to the drying processing chamber, controls the drying processing chamber to perform the drying processing of the substrate W, and controls the center robot CR to receive the substrate W dried in the drying processing chamber by the dry substrate hand 81 and transfer the substrate W to the indexer robot IR. As described above, the configuration including the individual hands according to the wet state of the substrate W prevents the dry substrate from being transferred by the wet hand. According to the configuration of the present invention, it is possible to transfer the substrate while the dry state of the substrate is surely maintained.

### Embodiment 2

### 17. Overall Configuration

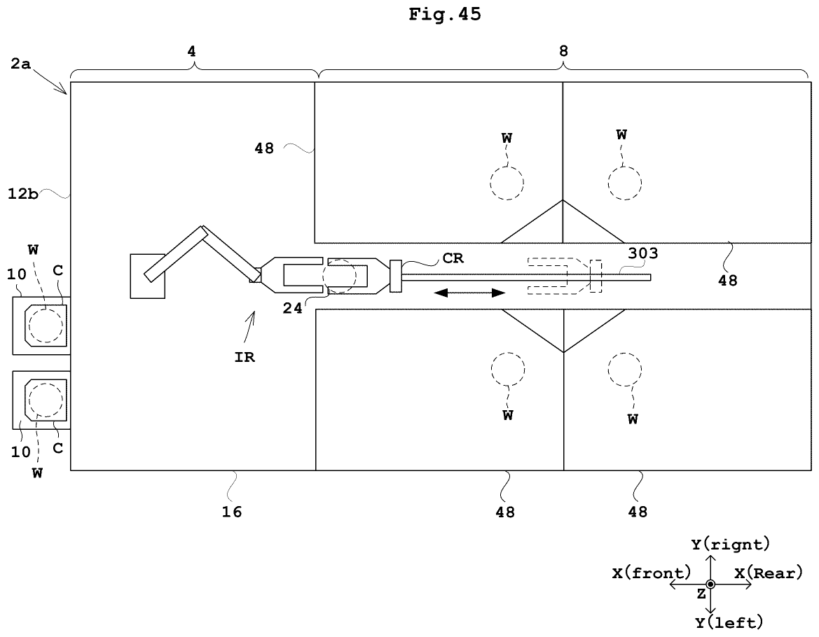

Next, a substrate processing apparatus 2a according to Embodiment 2 will be described. The substrate processing apparatus 2a according to Embodiment 2 is a single-substrate substrate processing apparatus that processes substrates W in a horizontal posture. FIG. 45 describes the substrate processing apparatus 2a according to the present embodiment. The substrate processing apparatus 2a has a configuration similar to that of the single substrate processing apparatus 2 included in the substrate processing system according to Embodiment 1.

That is, the substrate processing apparatus 2a of the present embodiment includes an indexer block 4 including an indexer robot IR that acquires an unprocessed substrate W from a carrier C and returns the substrate W that has been processed to the carrier C, and a single substrate processing block 8 including a single substrate processing chamber 48. A second load port 10 has a shelf-like configuration protruding from the indexer block 4, and the carrier C can be placed thereon.

The second load port 10, the indexer block 4, and the single substrate processing block 8 are specifically similar to those of the single substrate processing apparatus 2 of Embodiment 1 described above.

In the substrate processing apparatus 2a of the present embodiment, the indexer robot IR transfers the unprocessed substrates W stored in the carrier C in the second load port 10 one by one to a path 24. A center robot CR of the present embodiment acquires the unprocessed substrate W from the path 24, and transfers the processed substrate W to the path 24 instead. Then, the indexer robot IR of the present embodiment returns the processed substrate W placed on the path 24 to the carrier C. As described above, the substrate processing apparatus 2a transfers the substrates W in a manner different from that of the single substrate processing apparatus 2 according to Embodiment 1.

### 18. Single Substrate Processing Block

The substrate processing apparatus 2a of the present embodiment does not necessarily need to include the carry-out position OP of Embodiment 1. Since the substrate processing apparatus 2a of the present embodiment does not need to be provided with a carry-out position OP, a new single substrate processing chamber 48 is provided at a position where the carry-out position OP is provided in the single substrate processing apparatus 2 of Embodiment 1.

As described in Embodiment 1, the single substrate processing chamber 48 includes a plurality of drying processing chambers for performing substrate drying processing. The drying processing chambers may be one using a supercritical fluid or may be one of a spin dry type.

In addition, examples of the single substrate processing chamber of the present embodiment include a chemical liquid processing chamber that performs chemical liquid processing on the substrate W. Examples of the chemical liquid processing performed by the chemical liquid processing chamber include hydrofluoric acid processing for removing a natural oxide film grown on an upper surface of the substrate W, but are not limited thereto. The chemical liquid processing chamber acquires a dry substrate from the center robot CR, performs predetermined chemical liquid processing, and then fills a liquid on the substrate W and delivers the substrate W to the center robot CR. The liquid filled on the substrate W is, for example, pure water or IPA.

### 19. Control Unit

A control unit 132 of the present embodiment controls the indexer robot IR to extract the substrate W from the carrier C, and controls the center robot CR to receive, by the dry substrate hand 81, the substrate W extracted by the indexer robot IR and transfer the substrate W to a liquid supply chamber. Then, the control unit 132 controls the liquid supply chamber to fill the liquid on the substrate W, controls the center robot CR to receive, by the wet substrate hand 82, the liquid-filled substrate W filled in the liquid supply chamber and transfer the substrate W to the drying chamber, and controls the drying processing chamber to perform the drying processing on the substrate. Furthermore, the control unit 132 controls the center robot CR to receive, by the dry substrate hand 81, the substrate W dried in the drying chamber and transfer the substrate W to the indexer robot IR, and controls the indexer robot IR to return the dried substrate W to the carrier C.

### 20. Flow of Substrate Processing

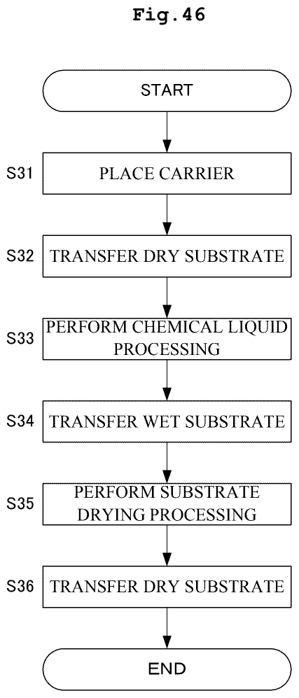

FIG. 46 is a flowchart for describing an operation of the substrate processing apparatus 2a of the present embodiment. Hereinafter, the flow of the substrate processing will be described with reference to this flowchart.

Step S31: The carrier C storing the unprocessed substrate W is placed in a second load port 10.

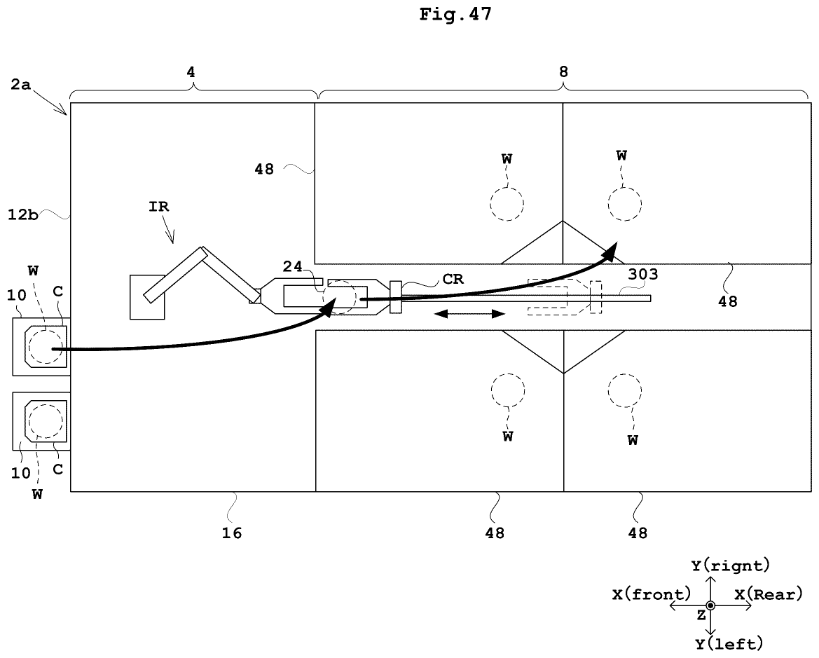

Step S32: The indexer robot IR extracts the unprocessed dry substrate from the carrier C in the second load port 10 and places the unprocessed dry substrate on the path 24. The center robot CR receives the dry substrate placed on the path 24 and transfers the dry substrate to a chemical liquid processing chamber which is a kind of the single substrate processing chamber 48. FIG. 47 illustrates the transfer path of the substrate W in steps S31 and S32.

In this step, the center robot CR transfers the substrate from the path 24 to the chemical liquid processing chamber, which is a kind of the single substrate processing chamber 48, using the dry substrate hand 81. As illustrated in FIG. 44, the dry substrate hand 81 transfers the substrate W while gripping the substrate W by distal end guides 811 and a hand pusher 83. At this time, since the substrate W is surely gripped by the dry substrate hand 81, the substrate can be transferred at high speed.

Step S33: The chemical liquid processing chamber, which is a kind of the single substrate processing chamber 48, supplies a predetermined chemical liquid to the substrate W to complete the chemical liquid processing. When a predetermined liquid is supplied to the upper surface of the substrate W that has been subjected to the chemical liquid processing, the substrate W gets in a paddle state. Examples of the predetermined liquid include pure water and IPA.

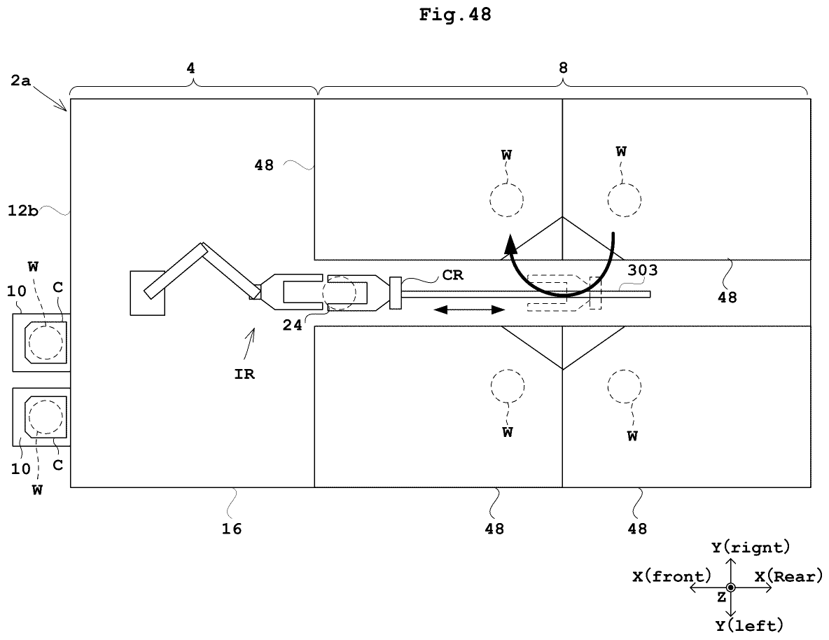

Step S34: The center robot CR receives the substrate W in the paddle state from the chemical liquid processing chamber, and transfers the substrate W to the drying processing chamber which is a kind of the single substrate processing chamber 48. FIG. 48 illustrates the transfer path of the substrate W in this step.

The transfer of the substrate in this step is performed using the wet substrate hand 82 in the center robot CR. As illustrated in FIG. 42, the wet substrate hand 82 can support and transfer the substrate W on which pure water or IPA is filled by distal end protrusions 821 and proximal end protrusions 822 provided at positions avoiding the end sides of the substrate W.

Step S35: The wet substrate W transferred to the drying processing chamber is subjected to a drying processing by the drying processing chamber.

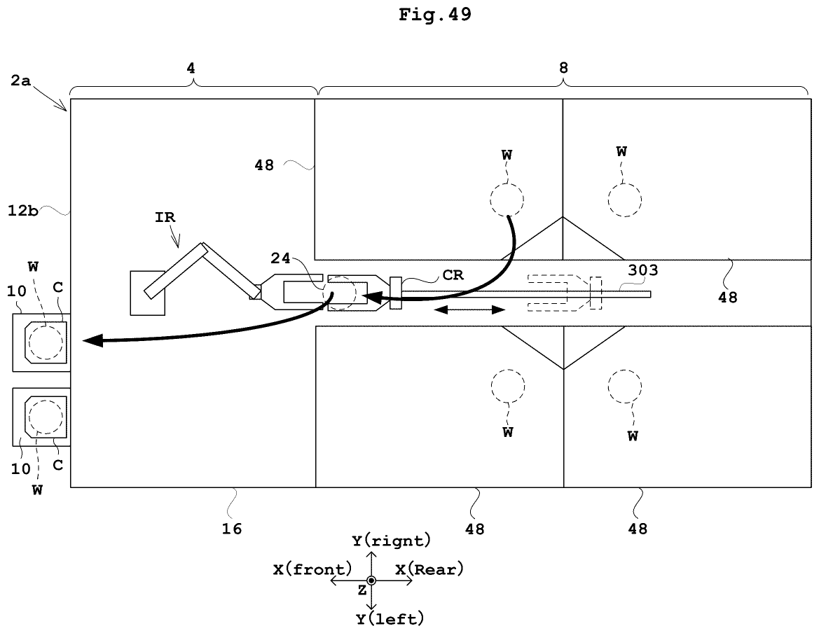

Step S36: When the drying processing of the substrate W is completed, the center robot CR receives the substrate from the drying processing chamber and transfers the substrate to the path 24. The center robot CR realizes this transfer using the dry substrate hand 81. The substrate W transferred to the path 24 is returned to the carrier C in the second load port 10 by the indexer robot IR. In this manner, the substrate processing of the present embodiment is completed. FIG. 49 illustrates the transfer path of the substrate W in this step.

### 21. Effects of Present Invention

According to the configuration of the present embodiment, the control unit 132 controls the center robot CR to receive, by the dry substrate hand 81, the substrate W extracted from the carrier C by the indexer robot IR and transfer the substrate W to the chemical liquid processing chamber, controls the chemical liquid processing chamber to fill a liquid on the substrate W, controls the center robot CR to receive, by the wet substrate hand 82, the liquid-filled substrate W filled by the chemical liquid processing chamber and transfer the substrate W to the drying processing chamber, controls the drying processing chamber to perform the drying processing of the substrate, and controls the center robot CR to receive the substrate W dried in the drying processing chamber by the dry substrate hand 81 and transfer the substrate W to the indexer robot IR. As described above, the configuration including the individual hands according to the wet state of the substrate W prevents the dry substrate from being transferred by the wet hand. According to the configuration of the present embodiment, it is possible to transfer the substrate W while the dry state of the substrate W is surely maintained.

### 22. Modification

The present invention is not limited to the above-described embodiments, and modifications can be made as follows.

### Modification 1

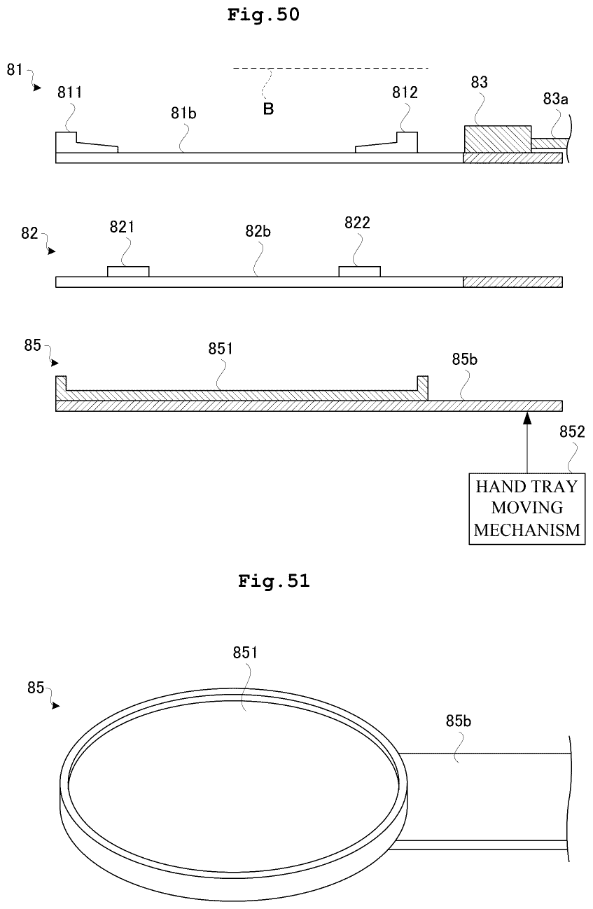

The center robot CR of the above-described embodiment includes the fixing vat 316 fixed to the robot base 301 and the moving vat 311 provided on the fixing vat 316, but the present invention is not limited to this configuration. As illustrated in FIG. 50, a tray hand 85 that receives a liquid flowing down from the liquid-filled substrate W placed below the wet substrate hand 82 may be provided. In the present modification, the fixing vat 316 and the moving vat 311 are not necessarily required.

A configuration of the tray hand 85 will be described. The tray hand 85 is provided below the wet substrate hand 82. The tray hand 85 includes a plate-shaped blade 85b extending on a horizontal plane and a hand tray 851 provided on an upper surface of the blade 85b. As illustrated in FIG. 51, the hand tray 851 has a disk shape, and a wall portion is provided so as to border the hand tray 851. This wall portion prevents the liquid pool generated on the upper surface of the hand tray 851 from flowing down below the hand tray 851. The size of the hand tray 851 is equal to or larger than the substrate W supported by the wet substrate hand 82. As a result, the liquid flowing down from the liquid-filled substrate W is surely received by the hand tray 851. The hand tray 851 corresponds to a tray of the present invention. The hand tray 851 receives the liquid dropping from the wet substrate hand 82.

A hand tray moving mechanism 852 advances and retreats the tray hand 85 in the extending direction B of the hand, and basically advances and retreats the hand tray 851 in synchronization with the wet substrate hand 82. That is, the hand tray moving mechanism 852 corresponds to a third moving mechanism of the present invention, and movably supports the tray hand 85 and is supported by the robot base 301. By the hand tray moving mechanism 852, the center of the hand tray 851 basically coincides with the center of the liquid-filled substrate W supported by the wet substrate hand 82. However, when the wet substrate hand 82 is located in a deep portion of the single substrate processing chamber 48 in order to introduce the substrate W into the single substrate processing chamber 48, the hand tray moving mechanism 852 causes the tray hand 85 to wait outside the single substrate processing chamber 48. With this configuration, a portion below the wet substrate hand 82 becomes empty inside the single substrate processing chamber 48. Such a state is advantageous when the substrate W is passed to a pin or a chuck inside the single substrate processing chamber 48.

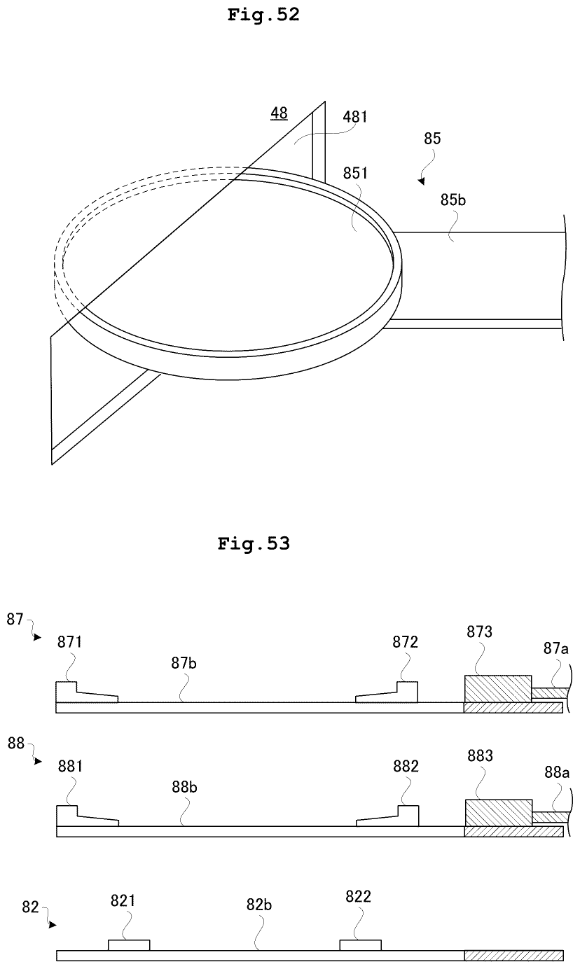

Actually, the hand tray moving mechanism 852 can move until half of the hand tray 851 is introduced into the carry-in port 481 of the single substrate processing chamber 48. That is, the hand tray 851 moves synchronously with the wet substrate hand 82 and stops when half of the substrate W is introduced into the carry-in port 481 (see FIG. 52). Thereafter, the wet substrate hand 82 further enters the single substrate processing chamber 48 with the hand tray 851 remaining. Even if the liquid flows down from the liquid-filled substrate W in a state where the wet substrate hand 82 moves with the hand tray 851 remaining, the liquid is received at the hand tray 851 or inside the single substrate processing chamber 48. The liquid flowing down from the liquid-filled substrate W does not scatter away from the center robot CR.

According to the above configuration, there are provided the tray hand 85 provided below the wet substrate hand 82 and the hand tray moving mechanism 852 that movably supports the tray hand 85 and is supported by the robot base 301, and the tray hand 85 includes the hand tray 851 that receives the liquid dropping from the wet substrate hand 82. With this configuration, since the hand tray 851 that faithfully follows the wet substrate hand 82 can be configured, the liquid filled on the substrate W can be made to be received by the hand tray 851. Therefore, according to the above configuration, it is possible to provide a substrate transfer apparatus capable of suppressing scattering of liquid. The tray hand 85 corresponds to a third hand of the present invention, and the hand tray moving mechanism 852 corresponds to the third moving mechanism of the present invention. The hand tray 851 corresponds to a third vat of the present invention.

### Modification 2

The present modification is particularly a modification of the substrate processing apparatus according to Embodiment 2. The center robot CR according to Embodiment 2 includes the single dry substrate hand 81, but a plurality of dry substrate hands 81 may be provided. The present modification particularly relates to the center robot CR in which two dry substrate hands 81 are prepared.

FIG. 53 describes a hand included in the center robot CR according to the present modification. As illustrated in FIG. 53, the center robot CR according to the present modification includes an upper hand 87 having a configuration similar to that of the dry substrate hand 81 described in Embodiment, and a lower hand 88 having a configuration similar to that of the dry substrate hand 81 described in the embodiment. The wet substrate hand 82 described in the embodiment is located below the lower hand 88.

The dry substrate hand of the present modification includes the upper hand 87 and the lower hand 88, which are two hands arranged vertically.

The lower hand 88 is a substrate gripping mechanism for transferring a dry substrate, and is a mechanism that performs substrate transfer described in FIG. 47, that is, transfer of an unprocessed substrate from the path 24 to the single substrate processing chamber 48. The lower hand 88 includes a flat branch blade 88b extending on a horizontal plane, distal end guides 881 provided at a distal end of the branch blade 88b, and proximal end guides 882 provided at a proximal end of the branch blade 88b. In addition, the lower hand 88 includes a hand pusher 883 that presses the end side of the substrate W at a proximal end portion of the branch blade 88b, and a hand pusher drive mechanism 88a that drives the hand pusher 883.

FIG. 30 illustrates a plan view of the lower hand 88. That is, the lower hand 88 includes a pair of distal end guides 881 (reference numeral 811 in FIG. 30) at the distal end of the branch blade 88b (reference numeral 81b in FIG. 30), and further includes a pair of proximal end guides 882 (reference numeral 812 in FIG. 30) at the proximal end of the branch blade 88b (reference numeral 81b in FIG. 30). The lower hand 88 can support the substrate W by the distal end guides 881 and the proximal end guides 882 in the opened state, and can grip the substrate W by the distal end guides 881 and the hand pusher 883 (reference numeral 83 in FIG. 30) in the closed state.

The upper hand 87 is a substrate gripping mechanism for transferring a dry substrate, and is a mechanism that performs substrate transfer described in FIG. 49, that is, transfer of a processed substrate from the path 24 to the single substrate processing chamber 48. The upper hand 87 includes a flat branch blade 87b extending on a horizontal plane, distal end guides 871 provided at a distal end of the branch blade 87b, and proximal end guides 872 provided at a proximal end of the branch blade 87b. In addition, the upper hand 87 includes a hand pusher 873 that presses the end side of the substrate W at a proximal end portion of the branch blade 87b, and a hand pusher drive mechanism 87a that drives the hand pusher 873.

FIG. 30 also illustrates a plan view of the upper hand 87. That is, the upper hand 87 includes a pair of distal end guides 871 (reference numeral 811 in FIG. 30) at the distal end of the branch blade 87b (reference numeral 81b in FIG. 30), and further includes a pair of proximal end guides 872 (reference numeral 812 in FIG. 30) at the proximal end of the branch blade 87b (reference numeral 81b in FIG. 30). The upper hand 87 can support the substrate W by the distal end guides 871 and the proximal end guides 872 in the opened state, and can grip the substrate W by the distal end guides 871 and the hand pusher 873 (reference numeral 83 in FIG. 30) in the closed state.

The upper hand 87 and the lower hand 88 can freely advance and retreat in the extending direction B of the hand, and also the upper hand 87 and the lower hand 88 can individually advance and retreat. With this configuration, only the upper hand 87 can be introduced into the single substrate processing chamber 48 to deliver the substrate W, or only the lower hand 88 can be introduced into the single substrate processing chamber 48 to deliver the substrate W. The first distal end arm 91 that supports the upper hand 87 and the lower hand 88 as described above is realized. The first distal end arm 91 is individually provided on the upper hand 87 and the lower hand 88, and can individually extend and contract in the extending direction B of the hand.

In this manner, each of the upper hand 87 and the lower hand 88 is movably supported by the first distal end arm 91 provided individually.

Note that since the upper hand 87 for processed substrate transfer is located above the lower hand 88 for unprocessed substrate transfer, particles or the like do not fall from the substrate W having low cleanliness gripped by the lower hand 88 to the substrate W having high cleanliness gripped by the upper hand 87. Since the particles tend to descend from the upper side to the lower side, it can be said that the configuration of the present modification is optimized in maintaining the cleanliness of the substrate W.

According to the above-described configuration, as the dry substrate hand, there are the upper hand 87 and the lower hand 88, which are two hands disposed vertically, and the upper hand 87 and the lower hand 88 are each movably supported by the first distal end arms 91 individually provided. With this configuration, the dry substrate before the substrate processing and the dry substrate after the substrate processing can be transferred by different hands. Therefore, it is possible to prevent the clean dry substrate after the substrate processing from being gripped by the hand contaminated by the dry substrate before the substrate processing. According to the above configuration, it is possible to provide a substrate transfer apparatus that improves reliability of substrate processing in a substrate processing apparatus.

What is claimed is:

1. A substrate transfer apparatus that transfers a substrate, the substrate transfer apparatus comprising:
at least one dry substrate hand for gripping a dry substrate in a horizontal posture;
a wet substrate hand provided below the dry substrate hand and for supporting a liquid-filled substrate;
a first moving mechanism that movably supports the dry substrate hand;
a second moving mechanism that movably supports the wet substrate hand; and
a base member that supports the first moving mechanism and the second moving mechanism, wherein
the dry substrate hand includes:
a first blade;
a pair of proximal end guides provided at a proximal end portion of the first blade and in contact with a substrate end portion;
a pair of distal end guides provided at a distal end portion of the first blade and in contact with the substrate end portion; and
a pusher for substrate gripping that is disposed at a position at the proximal end portion of the first blade and sandwiched between a pair of first proximal end guides, and is capable of gripping a substrate in cooperation with the distal end guides by coming into contact with an end side of the substrate and pressing the substrate toward the distal end guides, and
the wet substrate hand includes:
a second blade;
a pair of proximal end protrusions that is provided at a proximal end portion of the second blade and in contact with a lower surface of the substrate to support the substrate;
a pair of distal end protrusions that is provided at a distal end portion of the second blade and in contact with the lower surface of the substrate to support the substrate.

2. The substrate transfer apparatus according to claim 1, further comprising:
a fixing vat that is supported by the base member below the wet substrate hand and collects a liquid that has dropped from the wet substrate hand;
a moving vat that is provided between the wet substrate hand and the fixing vat, and receives the liquid that has dropped from the wet substrate hand and guides the liquid to the fixing vat; and
a moving vat advance/retreat mechanism that advances and retreats the moving vat in a horizontal direction with respect to the base member.

3. The substrate transfer apparatus according to claim 1, further comprising:
a tray hand provided below the wet substrate hand; and
a third moving mechanism that movably supports the tray hand and is supported by the base member, wherein
the tray hand includes a tray that receives a liquid dropping from the wet substrate hand.

4. The substrate transfer apparatus according to claim 1, wherein
the dry substrate hand includes an upper hand and a lower hand that are two hands disposed vertically, and
the upper hand and the lower hand are each movably supported by the first moving mechanism provided individually.

5. A substrate processing system that includes the substrate transfer apparatus according to claim 1, the substrate processing system comprising:
a batch processing apparatus that performs batch processing of collectively processing a plurality of substrates;
a relay apparatus that receives the plurality of substrates subjected to batch processing from the batch processing apparatus, converts each of the substrates into a horizontal posture, fills a liquid on the substrate in the horizontal posture, and transfers the substrate;
a single substrate processing apparatus that receives the liquid-filled substrate transferred to the relay apparatus and performs single substrate processing of processing the substrates one by one; and
a control unit that controls the batch processing apparatus, the single substrate processing apparatus, and the relay apparatus, wherein
the single substrate processing apparatus includes:
a drying chamber capable of drying the substrates one by one;
the substrate transfer apparatus; and
an indexer robot that returns the dried substrate to a carrier, and
the control unit
controls the substrate transfer apparatus to receive the liquid-filled substrate by the wet substrate hand and transfer the substrate to the drying chamber,
controls the drying chamber to perform drying processing of a substrate,
controls the substrate transfer apparatus to receive the substrate dried in the drying chamber by the dry substrate hand and transfer the substrate to the indexer robot, and
controls the indexer robot to return the dried substrate to the carrier.

6. A substrate processing apparatus that includes the substrate transfer apparatus according to claim 1 and performs single substrate processing of processing substrates one by one, the substrate processing apparatus comprising:
an indexer robot that transfers a substrate in an apparatus;
a processing block that performs substrate processing; and
a control unit that controls the apparatus, wherein
the processing block includes:
a liquid supply chamber that fills a liquid on a substrate;
a drying chamber that receives the liquid-filled substrate and perform drying processing; and
the substrate transfer apparatus, and
the control unit
controls the indexer robot to extract the substrate from a carrier,
controls the substrate transfer apparatus to receive the substrate extracted from the indexer robot by the dry substrate hand and transfer the substrate to the liquid supply chamber,
controls the liquid supply chamber to fill a liquid on the substrate,
controls the substrate transfer apparatus to receive, by the wet substrate hand, the liquid-filled substrate filled by the liquid supply chamber and transfer the substrate to the drying chamber,
controls the drying chamber to perform drying processing of the substrate,
controls the substrate transfer apparatus to receive the substrate dried in the drying chamber by the dry substrate hand and transfer the substrate to the indexer robot, and
controls the indexer robot to return the dried substrate to the carrier.
